(19) United States
(12) Patent Application Publication
(10) Pub. No.: US 2025/0311501 A1
(43) Pub. Date: Oct. 2, 2025

(54) DISPLAY DEVICE AND METHOD OF MANUFACTURING THE SAME

(71) Applicant: Samsung Display Co., LTD., Yongin-si (KR)

(72) Inventors: Moon Jung AN, Yongin-si (KR); Jin Seok PARK, Yongin-si (KR); Hoo Keun PARK, Yongin-si (KR)

(21) Appl. No.: 19/017,360

(22) Filed: Jan. 10, 2025

(30) Foreign Application Priority Data
Mar. 29, 2024 (KR) 10-2024-0043083

(51) Int. Cl. H10H 29/24; H10K 59/12; H10K 59/131; H10K 59/90

(52) U.S. Cl. CPC H10H 29/24; H10K 59/1201; H10K 59/131; H10K 59/90

(57) ABSTRACT

A display device and a method of manufacturing the same are provided. The display device includes a substrate, a pixel electrode on the substrate, an organic layer on the pixel electrode, and a light emitting element on the organic layer. The light emitting element includes a semiconductor stack, a protective layer on a side surface of the semiconductor stack, and a contact electrode on the protective layer. A portion of the side surface of the semiconductor stack is exposed without being covered by the contact electrode, and the contact electrode is spaced from an upper surface of the semiconductor stack.

### CROSS-REFERENCE TO RELATED APPLICATION

The present application claims priority to and the benefit of Korean Patent Application No. 10-2024-0043083, filed on Mar. 29, 2024, in the Korean Intellectual Property Office, the entire disclosure of which is incorporated by reference herein.

### BACKGROUND

### 1. Field

Aspects of one or more embodiments of the present disclosure relate to a display device and a method of manufacturing the same.

### 2. Description of the Related Art

As the information society develops, demands for display devices for displaying images are increasing in various forms. The display devices may be flat panel display devices such as liquid crystal displays, field emission displays, and light emitting displays.

The light emitting displays include an organic light emitting display including an organic light emitting diode (OLED) element as a light emitting element and a micro-light emitting display including a micro-light emitting diode element (hereinafter, referred to as a micro-light emitting element) as a light emitting element. Because micro-light emitting diode elements are made of inorganic materials, they have less deterioration issues and thus a longer life than organic light emitting diode (OLED) elements.

### SUMMARY

Aspects and features of embodiments of the present disclosure provide a display device and a method of manufacturing the same, in which a contact electrode is not exposed on an upper surface of a semiconductor stack and thus can be prevented from being peeled off by a chemical solution and/or the like.

However, the present disclosure is not limited to those set forth herein. The above and other embodiments of the present disclosure will become more apparent to one of ordinary skill in the art to which the present disclosure pertains by referencing the detailed description of the present disclosure given below.

According to one or more embodiments of the present disclosure, a display device includes a substrate, a pixel electrode on the substrate, an organic layer on the pixel electrode, and a light emitting element on the organic layer. The light emitting element includes a semiconductor stack, a protective layer on a side surface of the semiconductor stack, and a contact electrode on the protective layer. A portion of the side surface of the semiconductor stack is exposed without being covered by the contact electrode, and the contact electrode is spaced from an upper surface of the semiconductor stack.

According to one or more embodiments, the semiconductor stack may further include a first semiconductor layer on the organic layer and including a first semiconductor material layer doped with a first conductivity type dopant, an active layer on the first semiconductor layer, and a second semiconductor layer on the active layer and including a second semiconductor material layer doped with a second conductivity type dopant. The contact electrode may be on an entire side surface of the first semiconductor layer, an entire side surface of the active layer, and a portion of a side surface of the second semiconductor layer.

According to one or more embodiments, the light emitting element may further include a conductive layer between the organic layer and the semiconductor stack, the contact electrode on the protective layer being connected to the conductive layer which is exposed without being covered by the protective layer.

According to one or more embodiments, a distance between the upper surface of the semiconductor stack and the contact electrode in a height direction of the light emitting element is greater than 100 nm.

According to one or more embodiments, the light emitting element further includes light extraction patterns on the upper surface of the semiconductor stack and has a concave cross-sectional shape.

According to one or more embodiments, a distance between the upper surface of the semiconductor stack and the contact electrode in a height direction of the light emitting element may be greater than a maximum length of one of the light extraction patterns in the height direction of the light emitting element.

According to one or more embodiments, the protective layer may include a first side area exposed on a side surface of the light emitting element without being covered by the contact electrode and a second side area covered by the contact electrode, and surface roughness of the first side area may be greater than surface roughness of the second side area.

According to one or more embodiments, the display device may further include a connection electrode connected to the pixel electrode through a connection hole penetrating the organic layer and connected to the contact electrode on the side surface of the light emitting element.

According to one or more embodiments, a distance between the upper surface of the semiconductor stack and the connection electrode in a height direction of the light emitting element may be greater than 100 nm.

According to one or more embodiments of the present disclosure, a display device includes a substrate, a pixel electrode on the substrate, an organic layer on the pixel electrode and a common electrode, and a light emitting element on the organic layer. The light emitting element includes a semiconductor stack, a conductive layer between the organic layer and the semiconductor stack, a protective layer on side surfaces of the conductive layer and side surfaces of the semiconductor stack, a first contact electrode on the protective layer and connected to the conductive layer exposed without being covered by the protective layer, and a second contact electrode on the protective layer and in a hole penetrating the conductive layer and a portion of the semiconductor stack. Each of the first contact electrode and the second contact electrode is spaced from an upper surface of the semiconductor stack.

According to one or more embodiments, a portion of a first side surface from among the side surfaces of the semiconductor stack is exposed without being covered by the first contact electrode, and a portion of a second side surface among the side surfaces of the semiconductor stack is exposed without being covered by the second contact electrode.

According to one or more embodiments, the semiconductor stack may further include a first semiconductor layer on the organic layer and including a first semiconductor material layer doped with a first conductivity type dopant, an active layer on the first semiconductor layer, and a second semiconductor layer on the active layer and including a second semiconductor material layer doped with a second conductivity type dopant. The first contact electrode may be on a first side surface of the first semiconductor layer, a first side surface of the active layer, and a portion of a first side surface of the second semiconductor layer, and the second contact electrode is on a second side surface of the first semiconductor layer, a second side surface of the active layer, and a portion of a second side surface of the second semiconductor layer.

According to one or more embodiments, a distance between the upper surface of the semiconductor stack and the first contact electrode or the second contact electrode in a height direction of the light emitting element may be greater than 100 nm.

According to one or more embodiments, the light emitting element may further include a light extraction pattern on the upper surface of the semiconductor stack and has a concave cross-sectional shape.

According to one or more embodiments, a distance between the upper surface of the semiconductor stack and the first contact electrode or the second contact electrode in a height direction of the light emitting element may be greater than a maximum length of the light extraction pattern in the height direction of the light emitting element.

According to one or more embodiments, the protective layer may include a first side area exposed on a side surface of the light emitting element without being covered by the first contact electrode or the second contact electrode and a second side area covered by the first contact electrode or the second contact electrode, and surface roughness of the first side area may be greater than surface roughness of the second side area.

According to one or more embodiments, the display device may further include a first connection electrode connected to the pixel electrode through a first connection hole penetrating the organic layer and connected to the first contact electrode on a side surface of the light emitting element, and a second connection electrode connected to the common electrode through a second connection hole penetrating the organic layer and connected to the second contact electrode on another side surface of the light emitting element.

According to one or more embodiments, a distance between the upper surface of the semiconductor stack and the first connection electrode or the second connection electrode in a height direction of the light emitting element may be greater than 100 nm.

According to one or more embodiments of the present disclosure, a method of manufacturing a display device, the method includes forming a second semiconductor material layer, an active material layer, a first semiconductor material layer, and a conductive material layer on a semiconductor substrate, forming light emitting elements, each of the light emitting elements including a second semiconductor layer, an active layer, a first semiconductor layer and a conductive layer, by etching the second semiconductor material layer, the active material layer, the first semiconductor material layer, and the conductive material layer, forming a hole, which penetrates the conductive layer, the first semiconductor layer and the active layer, in each of the light emitting elements, forming a protective material layer which surrounds each of the light emitting elements and forming a protective layer by patterning the protective material layer, forming a mask pattern on the protective layer and forming a contact electrode layer, forming a first contact electrode connected to the conductive layer in each of the light emitting elements and a second contact electrode connected to the second semiconductor layer in the hole by removing the mask pattern, transferring the light emitting elements onto an organic layer on pixel electrodes and common electrodes such that the conductive layer in each of the light emitting elements faces a corresponding pixel electrode of the pixel electrodes and a corresponding common electrode of the common electrodes, and forming a first connection electrode which connects the first contact electrode of each of the light emitting elements to one of the pixel electrodes and a second connection electrode which connects the second contact electrode to one of the common electrodes.

According to one or more embodiments, the mask pattern may include a first sub-mask pattern area extending in a first direction and has a first thickness, and a second sub-mask pattern area having a thickness smaller than the first thickness and has a gradually smaller thickness along a second direction intersecting the first direction as a distance from the first sub-mask pattern area increases.

According to one or more embodiments of the present disclosure, a contact electrode of a light emitting element is spaced from an upper surface of a semiconductor stack. Therefore, the contact electrode can be prevented from being peeled off by a chemical solution or the like, unlike when exposed on the upper surface of the semiconductor stack.

### BRIEF DESCRIPTION OF THE DRAWINGS

The above and other aspects and features of the present disclosure will become more apparent by describing in detail embodiments thereof with reference to the attached drawings, in which:

FIG. 1 is a perspective view of a display device according to one or more embodiments;

FIG. 2 is a layout view of a display device according to one or more embodiments;

FIG. 3 is a block diagram of a display device according to one or more embodiments;

FIG. 4 is an equivalent circuit diagram of a subpixel according to one or more embodiments;

FIG. 5 is a layout view illustrating pixels of a display area according to one or more embodiments;

FIG. 6 is a cross-sectional view illustrating an example of a cross section of a display panel corresponding to the line I1-I1′ of FIG. 5;

FIG. 7 is a detailed cross-sectional view of an example of an area A1 of FIG. 6;

FIG. 8 is an image of a first side area;

FIG. 9 is an enlarged image of area S1 of the first side area;

FIG. 10 is an image of a second side area;

FIG. 11 is a detailed cross-sectional view of another example of the area A1 of FIG. 6;

FIG. 12 is a detailed cross-sectional view of another example of the area A1 of FIG. 6;

FIG. 13 is a cross-sectional view illustrating another example of the cross section of the display panel corresponding to the line I1-I1′ of FIG. 5;

FIG. 14 is a detailed cross-sectional view of an example of an area A2 of FIG. 13;

FIG. 15 is a layout view illustrating pixels of a display area according to one or more embodiments;

FIG. 16 is a cross-sectional view illustrating an example of a cross section of a display panel corresponding to the line I2-I2′ of FIG. 15;

FIG. 17 is a detailed cross-sectional view of an example of an area B1 of FIG. 16;

FIG. 18 is a cross-sectional view illustrating another example of the cross-section of the display panel corresponding to the line I2-I2′ of FIG. 15;

FIG. 19 is a detailed cross-sectional view of an example of an area B2 of FIG. 18;

FIG. 20 is a flowchart illustrating a method of manufacturing a display device according to one or more embodiments;

FIGS. 21 through 29 are example views for explaining the method of manufacturing the display device according to one or more embodiments;

FIG. 30 is a layout view illustrating light emitting elements and a second mask pattern in operation S140 of FIG. 20;

FIG. 31 is a cross-sectional view illustrating an example of a cross section corresponding to the line I3-I3′ of FIG. 30;

FIG. 32 is an example view of a smart watch including a display device according to one or more embodiments;

FIGS. 33 and 34 are example views of a virtual reality (VR) device including a display device according to one or more embodiments;

FIG. 35 is an example view of a VR device including a display device according to one or more embodiments;

FIG. 36 is an example view illustrating a vehicle instrument cluster and center fascia including display devices according to one or more embodiments; and

FIG. 37 is an example view of a transparent display device including a display device according to one or more embodiments.

### DETAILED DESCRIPTION

Aspects and features of embodiments of the present disclosure and methods of accomplishing the same may be understood more readily by reference to the detailed description of embodiments and the accompanying drawings. Hereinafter, aspects of some embodiments will be described in more detail with reference to the accompanying drawings. The described embodiments, however, may be embodied in various different forms, and should not be construed as being limited to only the illustrated embodiments herein. Rather, these embodiments are provided as examples so that the present disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure might not be described.

Unless otherwise noted, like reference numerals, characters, or combinations thereof denote like elements throughout the attached drawings and the written description, and thus, descriptions thereof will not be repeated. Further, parts not related to the description of one or more embodiments might not be shown to make the description clear.

In the drawings, the relative sizes of elements, layers, and regions may be exaggerated for clarity. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result, for example, of manufacturing techniques and/or tolerances, are to be expected. Further, specific structural or functional descriptions disclosed herein are merely illustrative for the purpose of describing embodiments according to the present disclosure. Thus, embodiments disclosed herein should not be construed as limited to the particular illustrated shapes of regions, but are to include deviations in shapes that result from, for instance, manufacturing.

For example, an implanted region illustrated as a rectangle may have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the drawings are schematic in nature and their shapes are not intended to illustrate the actual shape of a region of a device and are not intended to be limiting. Additionally, as those skilled in the art would realize, the described embodiments may be modified in various different ways, all without departing from the spirit and/or scope of the present disclosure.

In the detailed description, for the purposes of explanation, numerous specific details are set forth to provide a thorough understanding of various embodiments. It is apparent, however, that various embodiments may be practiced without these specific details or with one or more equivalent arrangements. In other instances, well-known structures and devices are shown in block diagram form to avoid unnecessarily obscuring various embodiments.

Spatially relative terms, such as “beneath,” “below,” “lower,” “under,” “above,” “upper,” and/or the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, in this specification, the phrase “on a plane,” or “in a plan view,” means viewing a target portion from the top, and the phrase “on a cross-section” means viewing a cross-section formed by vertically cutting a target portion from the side.

It will be understood that when an element, layer, region, or component is referred to as being “formed on,” “on,” “connected to,” or “coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. For example, when a layer, region, or component is referred to as being “electrically connected” or “electrically coupled” to another layer, region, or component, it can be directly electrically connected or coupled to the other layer, region, and/or component or intervening layers, regions, or components may be present. However, “directly connected/directly coupled” refers to one component directly connecting or coupling another component without an intermediate component. Meanwhile, other expressions describing relationships between components such as “between,” “immediately between” or “adjacent to” and “directly adjacent to” may be construed similarly. In addition, it will also be understood that when an element or layer is referred to as being “between” two elements or layers, it can be the only element or layer between the two elements or layers, or one or more intervening elements or layers may also be present.

For the purposes of the present disclosure, expressions such as “at least one of,” “one of,” and “selected from,” when preceding a list of elements, modify the entire list of elements and do not modify the individual elements of the list. For example, “at least one of X, Y, and Z,” “at least one of X, Y, or Z,” and “at least one selected from the group consisting of X, Y, and Z” may be construed as X only, Y only, Z only, any combination of two or more of X, Y, and Z, such as, for instance, XYZ, XYY, XZ, YZ, and ZZ, or any variation thereof. Similarly, the expression such as “at least one of A and/or B” may include A, B, or A and B. As used herein, the term “and/or” includes any and all combinations of one or more of the associated listed items. For example, the expression such as “A and/or B” may include A, B, or A and B. Further, the use of “may” when describing embodiments of the present disclosure refers to “one or more embodiments of the present disclosure”.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing particular embodiments only and is not intended to be limiting of the present disclosure. As used herein, the singular forms “a” and “an” are intended to include the plural forms as well, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

As used herein, the term “substantially,” “about,” “approximately,” and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.”

When one or more embodiments may be implemented differently, a specific process order may be performed differently from the described order. For example, two consecutively described processes may be performed substantially at the same time or performed in an order opposite to the described order.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, for example, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. § 112(a) and 35 U.S.C. § 132(a).

The electronic or electric devices and/or any other relevant devices or components according to one or more embodiments of the present disclosure described herein may be implemented utilizing any suitable hardware, firmware (e.g., an application-specific integrated circuit), software, or a combination of software, firmware, and hardware. For example, the various components of these devices may be formed on one integrated circuit (IC) chip or on separate IC chips. Further, the various components of these devices may be implemented on a flexible printed circuit film, a tape carrier package (TCP), a printed circuit board (PCB), or formed on one substrate.

Further, the various components of these devices may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, and/or the like. Also, a person of skill in the art should recognize that the functionality of various computing devices may be combined or integrated into a single computing device, or the functionality of a particular computing device may be distributed across one or more other computing devices without departing from the spirit and scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning for example consistent with their meaning in the context of the relevant art and/or the present specification, and should not be interpreted in an idealized or overly formal sense, unless expressly so defined herein.

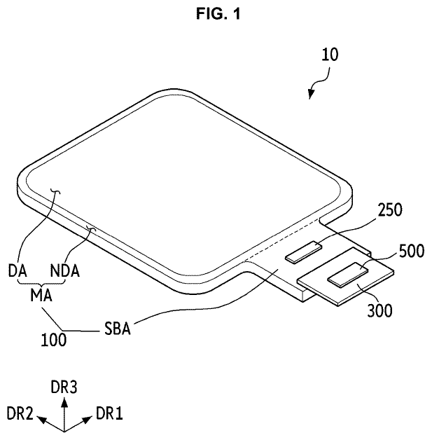

FIG. 1 is a perspective view of a display device 10 according to one or more embodiments.

Referring to FIG. 1, the display device 10 is a device for displaying moving images and/or still images. The display device 10 may be used as a display screen in portable electronic devices such as mobile phones, smartphones, tablet personal computers (PCs), smart watches, watch phones, mobile communication terminals, electronic notebooks, electronic books, portable multimedia players (PMPs), navigation devices and ultra-mobile PCs (UMPCs), as well as in various products such as televisions, notebook computers, monitors, billboards, and/or Internet of things (IoT) devices.

The display device 10 may be a light emitting display such as an organic light emitting display using an organic light emitting diode (OLED), a quantum dot light emitting display including a quantum dot light emitting layer, an inorganic light emitting display including an inorganic semiconductor, or a micro-or nano-light emitting display using a micro-or nano-light emitting diode (LED). A case where the display device 10 is a micro-or nano-light emitting display will be mainly described below, but the present disclosure is not limited thereto. For ease of description, a micro-or nano-LED will be referred to as a light emitting element.

The display device 10 includes a display panel 100, a display driving circuit 250, a circuit board 300, and a power supply unit 500.

The display panel 100 may be shaped like a rectangular plane having short sides in a first direction DR1 and long sides in a second direction DR2 intersecting the first direction DR1. Each corner where a short side extending in the first direction DR1 meets a long side extending in the second direction DR2 may be rounded to have a suitable curvature (e.g., a predetermined curvature) or may be right-angled. The planar shape of the display panel 100 is not limited to a quadrangular shape but may also be other polygonal shapes, a circular shape, and/or an elliptical shape. The display panel 100 may be formed flat, but the present disclosure is not limited thereto. For example, the display panel 100 may include a curved portion formed at left and right ends and having a constant or varying curvature. In addition, the display panel 100 may be formed to be flexible so that it can be curved, bent, folded, and/or rolled.

A substrate SUB of the display panel 100 may include a main area MA and a sub-area SBA.

The main area MA may include a display area DA which displays an image and a non-display area NDA disposed around the display area DA along an edge or a periphery of the display area DA. The display area DA may include a plurality of pixels that displays an image. Each of the pixels may include a plurality of subpixels. For example, each of the pixels may include a first subpixel that emits light of a first color, a second subpixel that emits light of a second color, and a third subpixel that emits light of a third color, but the present disclosure is not limited thereto.

The sub-area SBA may protrude from a side of the main area MA in the second direction DR2. Although the sub-area SBA is unfolded in FIG. 1, it may be bent. In this case, the sub-area SBA may be placed on a lower surface of the display panel 100. When the sub-area SBA is bent, it may be overlapped by the main area MA in a third direction DR3 which is a thickness direction of the display panel 100. The display driving circuit 250 may be disposed in the sub-area SBA.

The display driving circuit 250 may generate signals and voltages for driving the display panel 100. The display driving circuit 250 may be formed as an integrated circuit (IC) and attached onto the display panel 100 using a chip on glass (COG) method, a chip on plastic (COP) method, and/or an ultrasonic bonding method. However, the present disclosure is not limited thereto. For example, the display driving circuit 250 may also be attached onto the circuit board 300 using a chip on film (COF) method.

The circuit board 300 may be attached to an end of the sub-area SBA of the display panel 100. Accordingly, the circuit board 300 may be electrically connected to the display panel 100 and the display driving circuit 250. The display panel 100 and the display driving circuit 250 may receive digital video data, timing signals, and driving voltages through the circuit board 300. The circuit board 300 may be a flexible printed circuit board (FPCB), a printed circuit board (PCB), or a flexible film such as a chip on film (COF).

The power supply unit 500 may generate a plurality of panel driving voltages according to a power supply voltage from the outside. The power supply unit 500 may be formed as an integrated circuit (IC) and attached onto the circuit board 300 using a COF method.

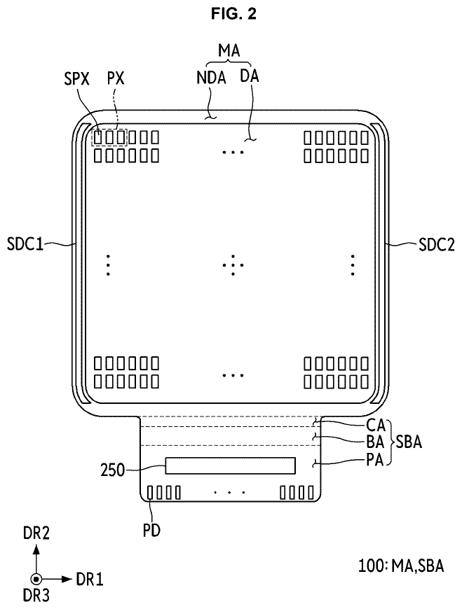

FIG. 2 is a layout view of the display device 10 according to one or more embodiments. FIG. 2 illustrates a state in which the sub-area SBA is unfolded without being bent.

Referring to FIG. 2, the display panel 100 may include the main area MA and the sub-area SBA.

The main area MA may include the display area DA that displays an image and the non-display area NDA disposed around the display area DA. The display area DA may occupy most of the main area MA. The display area DA may be disposed in a center of the main area MA.

The display area DA may include a plurality of pixels PX for displaying an image, and each of the pixels PX may include a plurality of subpixels SPX. A pixel PX may be defined as a smallest subpixel group that can express a white gray level.

The non-display area NDA may neighbor the display area DA. The non-display area NDA may be an area outside the display area DA. The non-display area NDA may be around (e.g., may surround) the display area DA. The non-display area NDA may be an edge area of the display panel 100.

A first scan driver SDC1 and a second scan driver SDC2 may be disposed in the non-display area NDA. The first scan driver SDC1 may be disposed on a side (e.g., a left side) of the display panel 100, and the second scan driver SDC2 may be disposed on the other side (e.g., a right side) of the display panel 100. However, the present disclosure is not limited thereto.

Each of the first scan driver SDC1 and the second scan driver SDC2 may be electrically connected to the display driving circuit 250 through scan fan-out lines. Each of the first scan driver SDC1 and the second scan driver SDC2 may receive a scan control signal from the display driving circuit 250, generate scan signals according to the scan control signal, and output the scan signals to scan lines.

The sub-area SBA may protrude from a side of the main area MA in the second direction DR2. A length of the sub-area SBA in the second direction DR2 may be smaller than a length of the main area MA in the second direction DR2. A length of the sub-area SBA in the first direction DR1 may be smaller than a length of the main area MA in the first direction DR1 or may be substantially equal to the length of the main area MA in the first direction DR1. The sub-area SBA may be bent and placed under the display panel 100. In this case, the sub-area SBA may be overlapped by the main area MA in the third direction DR3.

The sub-area SBA may include a connection area CA, a pad area PA, and a bending area BA.

The connection area CA is an area protruding from a side of the main area MA in the second direction DR2. A side of the connection area CA may contact the non-display area NDA of the main area MA, and the other side of the connection area CA may contact the bending area BA.

The pad area PA is an area where pads PD and the display driving circuit 250 are disposed. The display driving circuit 250 may be attached to driving pads of the pad area PA using a conductive adhesive member such as an anisotropic conductive film. The circuit board 300 may be attached to the pads PD of the pad area PA using a conductive adhesive member such as an anisotropic conductive film. A side of the pad area PA may contact the bending area BA.

The bending area BA is a bendable area. When the bending area BA is bent, the pad area PA may be placed under the connection area CA and the main area MA. The bending area BA may be disposed between the connection area CA and the pad area PA. A side of the bending area BA may contact the connection area CA, and the other side of the bending area BA may contact the pad area PA.

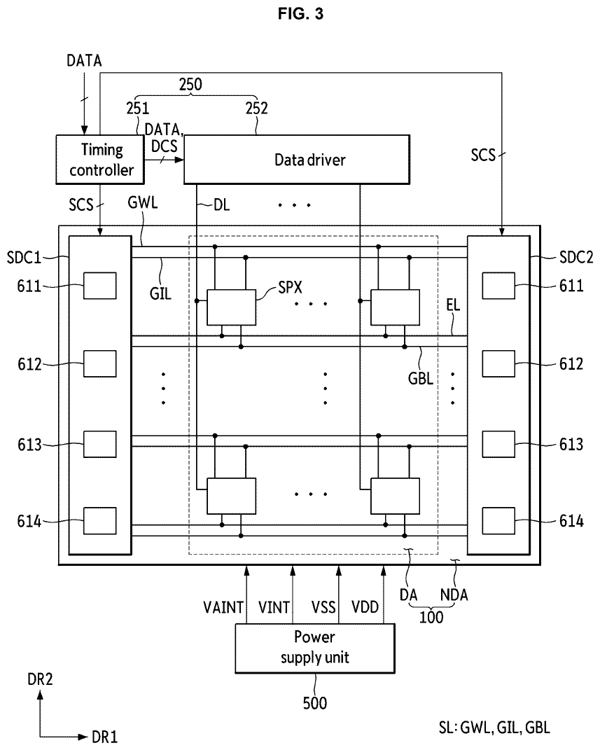

FIG. 3 is a block diagram of the display device 10 according to one or more embodiments.

Referring to FIG. 3, the display area DA includes a plurality of pixels PX, a plurality of scan lines SL, a plurality of emission control lines EL, and a plurality of data lines DL.

The pixels PX may be arranged in a matrix form along the first direction DR1 and the second direction DR2. For example, the pixels PX may be arranged along rows and columns of a matrix form along the first direction DR1 and the second direction DR2. The scan lines SL and the emission control lines EL may extend in the first direction DR1 and may be arranged along the second direction DR2. The data lines DL may extend in the second direction DR2 and may be arranged along the first direction DR1. The scan lines SL include a plurality of write scan lines GWL, a plurality of initialization scan lines GIL, and a plurality of bias scan lines GBL.

Each of the subpixels SPX may be connected to one of the write scan lines GWL, one of the initialization scan lines GIL, one of the bias scan lines GBL, one of the emission control lines EL, and one of the data lines DL. In one or more embodiments, each of the subpixels SPX may also be connected to one of the control scan lines.

Each of the subpixels SPX may receive a data voltage of a data line DL according to a write scan signal of a write scan line GWL and may emit light from a light emitting element according to the data voltage.

The non-display area NDA includes the first scan driver SDC1, the second scan driver SDC2, and the display driving circuit 250.

Each of the first scan driver SDC1 and the second scan driver SDC2 may include a write scan signal output unit 611, an initialization scan signal output unit 612, a bias scan signal output unit 613, and an emission signal output unit 614. Each of the write scan signal output unit 611, the initialization scan signal output unit 612, the bias scan signal output unit 613, and the emission signal output unit 614 may receive a scan timing control signal SCS from a timing controller 251. The write scan signal output unit 611 may generate write scan signals according to the scan timing control signal SCS of the timing controller 251 and sequentially output the write scan signals to the write scan lines GWL. The initialization scan signal output unit 612 may generate initialization scan signals according to the scan timing control signal SCS and sequentially output the initialization scan signals to the initialization scan lines GIL. The bias scan signal output unit 613 may generate bias scan signals according to the scan timing control signal SCS and sequentially output the bias scan signals to the bias scan lines GBL. The emission signal output unit 614 may generate emission control signals according to the scan timing control signal SCS and sequentially output the emission control signals to the emission control lines EL. In one or more other embodiments, a control scan signal output unit of the first scan driver SDC1 and the second scan driver SDC2 may generate control scan signals according to the scan timing control signal SCS and sequentially output the control scan signals to the control scan lines.

The display driving circuit 250 includes the timing controller 251 and a data driver 252.

The data driver 252 may receive digital video data DATA and a data timing control signal DCS from the timing controller 251. The data driver 252 converts the digital video data DATA into analog data voltages according to the data timing control signal DCS and outputs the analog data voltages to the data lines DL. In this case, subpixels SPX may be selected by write scan signals of the first scan driver SDC1 and the second scan driver SDC2, and the data voltages may be supplied to the selected subpixels SPX.

The timing controller 251 may receive the digital video data DATA and timing signals from the outside. The timing controller 251 may generate the scan timing control signal SCS and the data timing control signal DCS for controlling the display panel 100 according to the timing signals. The timing controller 251 may output the scan timing control signal SCS to the first scan driver SDC1 and the second scan driver SDC2. The timing controller 251 may output the digital video data DATA and the data timing control signal DCS to the data driver 252.

The power supply unit 500 may generate a plurality of panel driving voltages according to a power supply voltage from the outside. For example, the power supply unit 500 may generate a first power supply voltage VDD, a second power supply voltage VSS, a third power supply voltage VINT, and a fourth power supply voltage VAINT and supply them to the display panel 100.

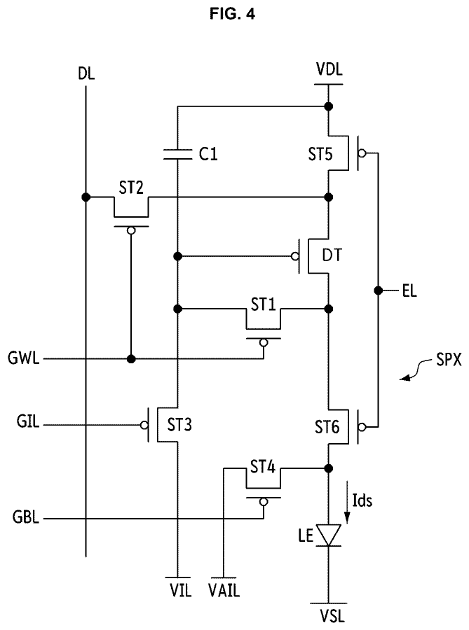

FIG. 4 is an equivalent circuit diagram of a subpixel SPX according to one or more embodiments.

Referring to FIG. 4, the subpixel SPX according to the embodiment may be connected to scan lines GWL, GIL, and GBL, an emission control line EL, and a data line DL. For example, the subpixel SPX may be connected to a write scan line GWL, an initialization scan line GIL, a bias scan line GBL, the emission control line EL, and the data line DL.

The subpixel SPX according to the embodiment includes a driving transistor DT, switch elements, a capacitor C1, and a light emitting element LE. The switch elements include first through sixth transistors ST1 through ST6.

The driving transistor DT includes a gate electrode, a first electrode, and a second electrode. The driving transistor DT controls a drain-source current Ids (hereinafter, referred to as a “driving current”) flowing between the first electrode and the second electrode according to a data voltage applied to the gate electrode.

The light emitting element LE may be a micro-LED.

The light emitting element LE emits light according to the driving current Ids. The amount of light emitted from the light emitting element LE may be proportional to the driving current Ids. An anode of the light emitting element LE may be connected to a first electrode of the fourth transistor ST4 and a second electrode of the sixth transistor ST6, and a cathode may be connected to a second power line VSL to which the second power supply voltage VSS is applied.

The capacitor C1 is formed between the gate electrode of the driving transistor DT and a first power line VDL to which the first power supply voltage VDD is applied. The first power supply voltage VDD may be at a higher level than the second power supply voltage VSS. One electrode of the capacitor C1 may be connected to the gate electrode of the driving transistor DT, and the other electrode may be connected to the first power line VDL.

As illustrated in FIG. 4, the first through sixth transistors ST1 through ST6 and the driving transistor DT may all be formed as p-type metal-oxide-semiconductor field effect transistors (MOSFETs). In this case, an active layer of each of the first through sixth transistors ST1 through ST6 and the driving transistor DT may be made of polysilicon.

A gate electrode of the first transistor ST1 and a gate electrode of the second transistor ST2 may be connected to the write scan line GWL, a gate electrode of the third transistor ST3 may be connected to the initialization scan line GIL, a gate electrode of the fourth transistor ST4 may be connected to the bias scan line GBL, and a gate electrode of the fifth transistor ST5 and a gate electrode of the sixth transistor ST6 may be connected to the emission control line EL. Because the first through sixth transistors ST1 through ST6 are formed as p-type MOSFETs, they may be turned on when a scan signal of a gate-low voltage and an emission control signal of a gate-low voltage are transmitted the initialization scan line GIL, the write scan line GWL, the bias scan line GBL, and the emission control line EL. One electrode of the third transistor ST3 and one electrode of the fourth transistor ST4 may be connected to an initialization voltage line VIL and the voltage line VAIL, respectively.

Alternatively, the driving transistor DT, the second transistor ST2, the fourth transistor ST4, the fifth transistor ST5 and the sixth transistor ST6 may be formed as p-type MOSFETs, and the first transistor ST1 and the third transistor ST3 may be formed as n-type MOSFETs. The active layer of each of the driving transistor DT, the second transistor ST2, the fourth transistor ST4, the fifth transistor ST5 and the sixth transistor ST6 formed as p-type MOSFETs may be made of polysilicon, and the active layer of each of the first transistor ST1 and the third transistor ST3 formed as n-type MOSFETs may be made of an oxide semiconductor.

In this case, because the first transistor ST1 and the third transistor ST3 are formed as n-type MOSFETs, the first transistor ST1 may be turned on in response to a write scan signal of a gate-high voltage, and the third transistor ST3 may be turned on in response to an initialization scan signal of a gate-high voltage. On the other hand, because the second transistor ST2, the fourth transistor ST4, the fifth transistor ST5, and the sixth transistor ST6 are formed as p-type MOSFETs, they may be turned on in response to a scan signal of a gate-low voltage and an emission control signal of a gate-low voltage.

Alternatively, the fourth transistor ST4 may be formed as an n-type MOSFET. In this case, the active layer of the fourth transistor ST4 may be made of an oxide semiconductor. When the fourth transistor ST4 is formed as an n-type MOSFET, it may be turned on in response to a bias scan signal of a gate-high voltage.

Alternatively, the first through sixth transistors ST1 through ST6 and the driving transistor DT may all be formed as n-type MOSFETs. In this case, the active layer of each of the first through sixth transistors ST1 through ST6 and the driving transistor DT may be made of an oxide semiconductor.

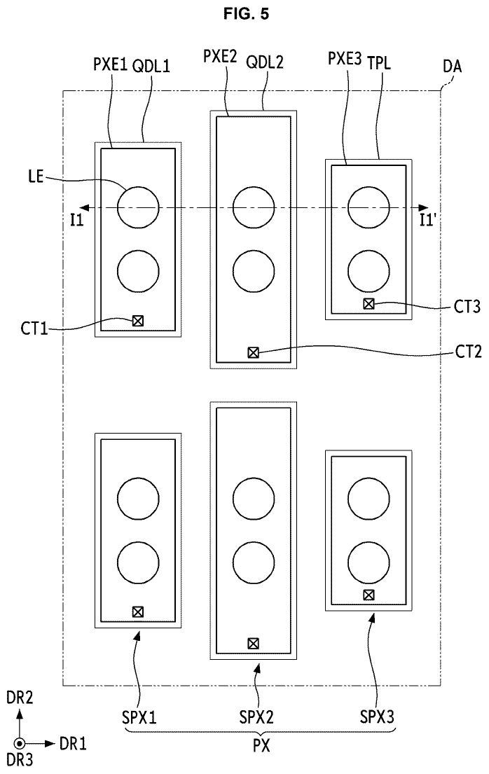

FIG. 5 is a layout view illustrating pixels PX of a display area DA according to one or more embodiments.

Referring to FIG. 5, each of the pixels PX in the display area DA may include three subpixels SPX1 through SPX3. However, the present disclosure is not limited thereto, and each of the pixels PX may also include four subpixels. When each of the pixels PX includes three subpixels SPX1 through SPX3, it may include a first subpixel SPX1, a second subpixel SPX2, and a third subpixel SPX3.

The pixels PX may be arranged in a matrix form. In each of the pixels PX, the first subpixel SPX1, the second subpixel SPX2, and the third subpixel SPX3 may be arranged along the first direction DR1.

When each of the pixels PX includes three subpixels SPX1 through SPX3, the first subpixel SPX1 may output light of a first color, the second subpixel SPX2 may output light of a second color, and the third subpixel SPX3 may output light of a third color. Here, the light of the first color may be light in a red wavelength band, the light of the second color may be light in a green wavelength band, and the light of the third color may be light in a blue wavelength band. For example, the blue wavelength band may indicate that a main peak wavelength of light is included in a wavelength band of about 370 to 460 nm, the green wavelength band may indicate that a main peak wavelength of light is included in a wavelength band of about 480 to 560 nm, and the red wavelength band may indicate that a main peak wavelength of light is included in a wavelength band of about 600 to 750 nm.

Alternatively, when each of the pixels PX includes four subpixels, a first subpixel may output light of the first color, a second subpixel and a fourth subpixel may output light of the second color, and a third subpixel may output light of the third color. Alternatively, the first subpixel may output light of the first color, the second subpixel may output light of the second color, the third subpixel may output light of the third color, and the fourth subpixel may output light of a fourth color. Here, the light of the fourth color may be white light.

The first subpixel SPX1 includes a first pixel electrode PXE1, a plurality of light emitting elements LE, and a first light conversion layer QDL1. The second subpixel SPX2 includes a second pixel electrode PXE2, a plurality of light emitting elements LE, and a second light conversion layer QDL2. The third subpixel SPX3 includes a third pixel electrode PXE3, a plurality of light emitting elements LE, and a light transmission layer TPL.

Each of the first pixel electrode PXE1, the second pixel electrode PXE2, and the third pixel electrode PXE3 may be shaped like a rectangular plane having short sides in the first direction DR1 and long sides in the second direction DR2. The area of the first subpixel SPX1, the area of the second subpixel SPX2, and the area of the third subpixel SPX3 may be set according to the light conversion efficiency of the first light conversion layer QDL1 and the light conversion efficiency of the second light conversion layer QDL2. For example, the lower the light conversion efficiency, the larger the area of a subpixel.

For example, as illustrated in FIG. 5, when the light conversion efficiency of the second light conversion layer QDL2 is lower than the light conversion efficiency of the first light conversion layer QDL1, the area of the second pixel electrode PXE2 may be larger than the area of the first pixel electrode PXE1. In addition, because the first light conversion layer QDL1 must convert light whereas the light transmission layer TPL transmits light of the light emitting elements LE as it is, the area of the first pixel electrode PXE1 may be larger than the area of the third pixel electrode PXE3.

Each of the pixel electrodes PXE1 through PXE3 may be electrically connected to at least one transistor through a pixel connection hole CT1/CT2/CT3. For example, each of the pixel electrodes PXE1 through PXE3 may be electrically connected to the first electrode of the fourth transistor ST4 (see FIG. 4) and the second electrode of the sixth transistor ST6 (see FIG. 4) of a corresponding subpixel.

A plurality of light emitting elements LE may be disposed on each of the pixel electrodes PXE1 through PXE3. The same number of light emitting elements LE may be disposed on each of the pixel electrodes PXE1 through PXE3. For example, two light emitting elements LE may be disposed on each of the pixel electrodes PXE1 through PXE3. The light emitting elements LE may emit light of the third color, that is, light in the blue wavelength band, but the present disclosure is not limited thereto.

Each of the light emitting elements LE may have a circular planar shape, but the present disclosure is not limited thereto. For example, each of the light emitting elements LE may have a quadrangular planar shape.

The first light conversion layer QDL1 may completely overlap the first pixel electrode PXE1 and the light emitting elements LE of the first subpixel SPX1. The area of the first light conversion layer QDL1 may be larger than the area of the first pixel electrode PXE1. The first light conversion layer QDL1 may convert or shift a peak wavelength of incident light into light of another specific peak wavelength and output the light of the specific peak wavelength. For example, the first light conversion layer QDL1 may convert or shift third light emitted from the light emitting elements LE of the first subpixel SPX1 into first light.

The second light conversion layer QDL2 may completely overlap the second pixel electrode PXE2 and the light emitting elements LE of the second subpixel SPX2. The area of the second light conversion layer QDL2 may be larger than the area of the second pixel electrode PXE2. The second light conversion layer QDL2 may convert or shift a peak wavelength of incident light into light of another specific peak wavelength and output the light of the specific peak wavelength. For example, the second light conversion layer QDL2 may convert or shift third light emitted from the light emitting elements LE of the second subpixel SPX2 into second light.

The light transmission layer TPL may completely overlap the third pixel electrode PXE3 and the light emitting elements LE of the third subpixel SPX3. The light transmission layer TPL may transmit incident light as it is. For example, the light transmission layer TPL may transmit third light emitted from the light emitting elements LE of the third subpixel SPX3 as it is.

When the light emitting elements LE of the first subpixel SPX1 emit light of the first color, the light emitting elements LE of the second subpixel SPX2 emit light of the second color, and the light emitting elements LE of the third subpixel SPX3 emit light of the third color, the light conversion layers QDL1 and QDL2 and the light transmission layer TPL may be omitted.

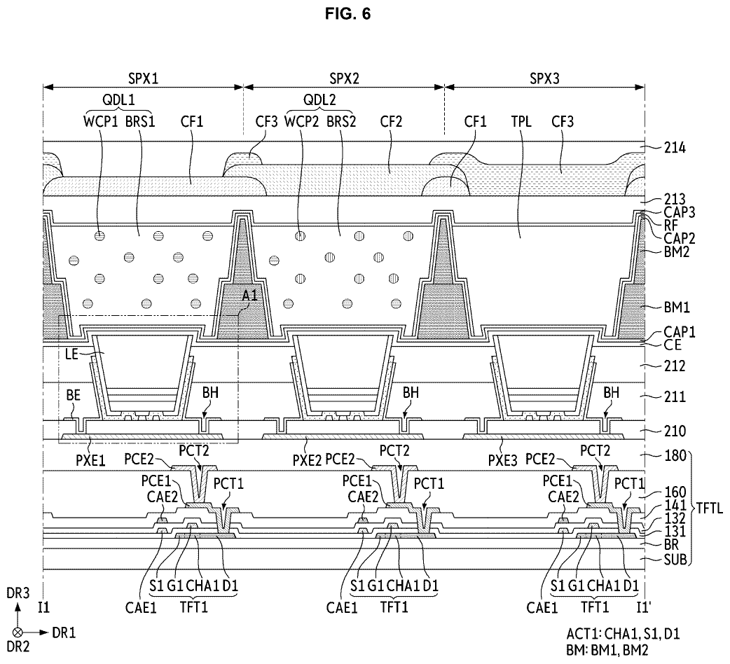

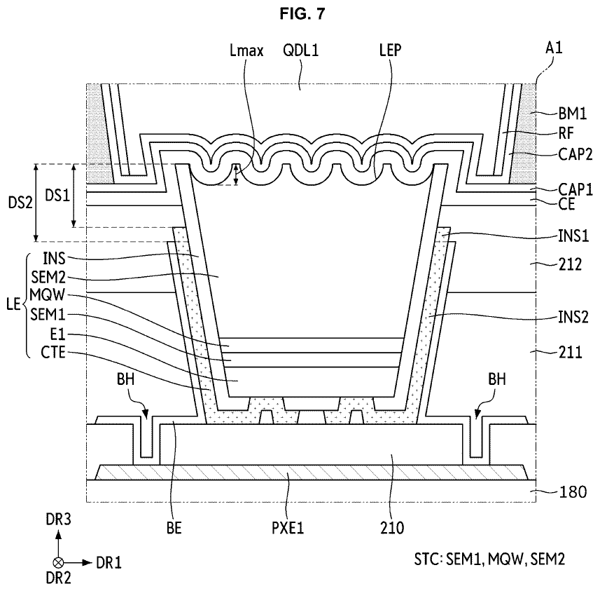

FIG. 6 is a cross-sectional view illustrating an example of a cross section of the display panel 100 corresponding to the line I1-I1′ of FIG. 5. FIG. 7 is a detailed cross-sectional view of an example of an area A1 of FIG. 6.

Referring to FIGS. 6 and 7, a substrate SUB may be made of an insulating material such as glass and/or polymer resin. When the substrate SUB is made of polymer resin, it may be a flexible substrate that can be stretched. The polymer resin may be acryl resin, epoxy resin, phenolic resin, polyamide resin, and/or polyimide resin.

A barrier layer BR may be disposed on the substrate SUB. The barrier layer BR is a layer for protecting transistors of a thin-film transistor layer TFTL from moisture introduced through the substrate SUB which is vulnerable to moisture penetration. The barrier layer BR may be composed of a plurality of inorganic layers stacked alternately.

Thin-film transistors TFT1 may be disposed on the barrier layer BR. Each of the thin-film transistors TFT1 may be one of the fourth transistor ST4 or the sixth transistor ST6 illustrated in FIG. 4. Each of the thin-film transistors TFT1 may include a first active layer ACT1 and a first gate electrode G1.

The first active layer ACT1 of each of the thin-film transistors TFT1 may be disposed on the barrier layer BR. The first active layer ACT1 of each of the thin-film transistors TFT1 may include polycrystalline silicon, monocrystalline silicon, low-temperature polycrystalline silicon, and/or amorphous silicon. Alternatively, the first active layer ACT1 of each of the thin-film transistors TFT1 may be made of an oxide semiconductor including IGZO (indium (In), gallium (Ga), zinc (Zn) and oxygen (O)), IGZTO (indium (In), gallium (Ga), zinc (Zn), tin (Sn) and oxygen (O)), and/or IGTO (indium (In), gallium (Ga), tin (Sn) and oxygen (O)).

The first active layer ACT1 may include a first channel region CHA1, a first source region S1, and a first drain region D1. The first channel region CHA1 may be a region overlapped by the first gate electrode G1 in the third direction DR3 which is the thickness direction of the substrate SUB. The first source region S1 may be disposed on a side of the first channel region CHA1, and the first drain region D1 may be disposed on the other side of the first channel region CHA1. The first source region S1 and the first drain region D1 may be regions not overlapped by the first gate electrode G1 in the third direction DR3. The first source region S1 and the first drain region D1 may be regions formed to have conductivity by doping a semiconductor material with ions.

A first gate insulating layer 131 may be disposed on the first channel regions CHA1, the first source regions S1, and the first drain regions D1 of the thin-film transistors TFT1 and the barrier layer BR.

A first gate metal layer may be disposed on the first gate insulating layer 131. The first gate metal layer may include the first gate electrodes G1 of the thin-film transistors TFT1 and first capacitor electrodes CAE1. The first gate electrodes G1 may overlap the first active layers ACT1 in the third direction DR3. In FIG. 6, the first gate electrodes G1 and the first capacitor electrodes CAE1 are spaced (e.g., spaced apart) from each other. However, the first gate electrodes G1 and the first capacitor electrodes CAE1 may also be connected to each other.

A second gate insulating layer 132 may be disposed on the first gate electrodes G1 of the thin-film transistors TFT1, the first capacitor electrodes CAE1 and the first gate insulating layer 131.

A second gate metal layer may be disposed on the second gate insulating layer 132. The second gate metal layer may include second capacitor electrodes CAE2. The second capacitor electrodes CAE2 may overlap the first capacitor electrodes CAE1 in the third direction DR3. Because the second gate insulating layer 132 has a suitable dielectric constant (e.g., a predetermined dielectric constant), a capacitor C1 (see FIG. 4) may be formed by the first capacitor electrodes CAE1, the second capacitor electrodes CAE2, and the second gate insulating layer 132 disposed between them.

A first interlayer insulating layer 141 may be disposed on the second capacitor electrodes CAE2 and the second gate insulating layer 132.

A first data metal layer may be disposed on the first interlayer insulating layer 141. The first data metal layer may include first source connection electrodes PCE1. The first source connection electrodes PCE1 may be connected to the first drain regions D1 of the first active layers ACT1 through first source contact holes PCT1 penetrating the first gate insulating layer 131, the second gate insulating layer 132, and the first interlayer insulating layer 141.

A first planarization organic layer 160 may be disposed on the first source connection electrodes PCE1 and the first interlayer insulating layer 141 to flatten steps caused by the thin-film transistors TFT1.

A second data metal layer may be disposed on the first planarization organic layer 160. The second data metal layer may include second source connection electrodes PCE2. The second source connection electrodes PCE2 may be connected to the first source connection electrodes PCE1 through second source contact holes PCT2 penetrating the first planarization organic layer 160.

A second planarization organic layer 180 may be disposed on the second source connection electrodes PCE2 and the first planarization organic layer 160.

The barrier layer BR, the first gate insulating layer 131, the second gate insulating layer 132, and the first interlayer insulating layer 141 may be made of an inorganic layer, for example, silicon nitride (SiNₓ), silicon oxynitride (SiON), silicon oxide (SiOₓ), titanium oxide (TiOₓ), and/or aluminum oxide (AlOₓ).

The first gate metal layer, the second gate metal layer, the first data metal layer, and the second data metal layer may each be a single layer or a multilayer made of molybdenum (Mo), aluminum (Al), chromium (Cr), gold (Au), titanium (Ti), nickel (Ni), neodymium (Nd), copper (Cu), and/or alloys thereof.

The first planarization organic layer 160 and the second planarization organic layer 180 may be made of an organic layer such as acryl resin, epoxy resin, phenolic resin, polyamide resin, and/or polyimide resin.

The light emitting element layer may be disposed on the second planarization organic layer 180. The light emitting element layer may include pixel electrodes PXE1 through PXE3, light emitting elements LE, a common electrode CE, and organic layers 210, 211 and 212.

A pixel electrode layer may be disposed on the second planarization organic layer 180. The pixel electrode layer may include a first pixel electrode PXE1, a second pixel electrode PXE2, and a third pixel electrode PXE3. Each of the pixel electrodes PXE1 through PXE3 may be connected to a second source connection electrode PCE2 through a connection hole CT1/CT2/CT3 (see FIG. 5) penetrating the second planarization organic layer 180. Each of the pixel electrodes PXE1 through PXE3 may be connected to the first source region S1 or the first drain region D1 of a thin-film transistor TFT1 through a first source connection electrode PCE1 and a second source connection electrode PCE2. Therefore, a voltage controlled by a thin-film transistor TFT1 may be applied to each of the pixel electrodes PXE1 through PXE3.

The pixel electrode layer may be a single layer or a multilayer made of molybdenum (Mo), aluminum (Al), chromium (Cr), gold (Au), titanium (Ti), nickel (Ni), neodymium (Nd), copper (Cu), and/or alloys thereof. For example, the pixel electrode layer may be made of copper (Cu) with low sheet resistance in order to lower the resistance of each of the pixel electrodes PXE1 through PXE3.

A first organic layer 210 may be disposed on each of the pixel electrodes PXE1 through PXE3 and the second planarization organic layer 180. The first organic layer 210 temporarily fixes or attaches a plurality of light emitting elements LE to prevent the light emitting elements LE from tilting or falling during a process of transferring the light emitting elements LE to the display panel 100. That is, the first organic layer 210 may be a layer for temporarily attaching a plurality of light emitting elements LE onto each of the pixel electrodes PXE1 through PXE3. To facilitate the temporary adhesion, the first organic layer 210 may be thicker than each of the pixel electrodes PXE1 through PXE3 and thicker than contact electrodes CTE.

The first organic layer 210 may be a photosensitive organic layer such as photoresist. Alternatively, the first organic layer 210 may be made of acryl resin, epoxy resin, phenolic resin, polyamide resin, and/or polyimide resin.

The light emitting elements LE may be disposed on the first organic layer 210. In FIGS. 6 and 7, each of the light emitting elements LE is a vertical type micro-LED extending in the third direction DR3. The vertical type micro-LED refers to an LED having a structure in which a first semiconductor layer SEM1, an active layer MQW, and a second semiconductor layer SEM2 are sequentially disposed in the third direction DR3 which is a vertical direction.

Each of the light emitting elements LE may have a reverse-tapered cross-sectional shape. For example, each of the light emitting elements LE may have a trapezoidal cross-sectional shape whose upper surface is wider than a lower surface.

Each of the light emitting elements LE may be made of an inorganic material such as gallium nitride (GaN). Each of the light emitting elements LE may have a length of several to hundreds of μm in each of the first direction DR1, the second direction DR2, and the third direction DR3. For example, each of the light emitting elements LE may have a length of about 100 μm or less in each of the first direction DR1, the second direction DR2, and the third direction DR3.

Each of the light emitting elements LE may be grown on a semiconductor substrate such as a silicon substrate or a sapphire substrate. The light emitting elements LE may be directly transferred from the semiconductor substrate onto the pixel electrodes PXE1 through PXE3 of the display panel 100. Alternatively, the light emitting elements LE may be transferred onto the pixel electrodes PXE1 through PXE3 of the display panel 100 through an electrostatic method using an electrostatic head or a stamp method using an elastic polymer material, such as PDMS or silicon, as a transfer substrate.

Each of the light emitting elements LE may include a conductive layer E1, a semiconductor stack STC, contact electrodes CTE, and a protective layer INS. The semiconductor stack STC may include the first semiconductor layer SEM1, the active layer MQW, and the second semiconductor layer SEM2 sequentially disposed in the third direction DR3.

The conductive layer E1 may be disposed on a lower surface of the first semiconductor layer SEM1. Although the conductive layer E1 covers the entire lower surface of the first semiconductor layer SEM1 in FIG. 7, the present disclosure is not limited thereto. For example, the conductive layer E1 may also be disposed on a portion of the lower surface of the first semiconductor layer SEM1. The conductive layer E1 may include molybdenum (Mo), aluminum (Al), chromium (Cr), gold (Au), titanium (Ti), nickel (Ni), neodymium (Nd), and/or copper (Cu).

The first semiconductor layer SEM1 may be disposed on the conductive layer E1. The first semiconductor layer SEM1 may be made of a semiconductor material layer, for example, gallium nitride (GaN) doped with a first conductivity type dopant such as magnesium (Mg), zinc (Zn), calcium (Ca), strontium (Sr), and/or barium (Ba).

The active layer MQW may be disposed on the first semiconductor layer SEM1. The active layer MQW may emit light through combination of electron-hole pairs according to electrical signals received through the first semiconductor layer SEM1 and the second semiconductor layer SEM2.

The active layer MQW may include a material having a single or multiple quantum well structure. When the active layer MQW includes a material having a multiple quantum well structure, it may be a structure in which a plurality of well layers and a plurality of barrier layers are alternately stacked. Here, the well layers may be made of InGaN, and the barrier layers may be made of GaN or AlGaN, but the present disclosure is not limited thereto.

Alternatively, the active layer MQW may be a structure in which a semiconductor material having a large band gap energy and a semiconductor material having a small band gap energy are alternately stacked or may include different group III to V semiconductor materials depending on the wavelength band of light that it emits.

For example, when the active layer MQW includes indium gallium nitride (InGaN), the color of light that it emits may vary according to indium content. For example, as the indium content increases, the wavelength band of light emitted from the active layer MQW may move to the red wavelength band, and as the indium content decreases, the wavelength band of light emitted from the active layer MQW may move to the blue wavelength band. For example, the indium content of the active layer MQW of a light emitting element LE which emits third light (light in the blue wavelength band) may be about 10 to 20 wt %.

The second semiconductor layer SEM2 may be disposed on the active layer MQW. The second semiconductor layer SEM2 may be made of a semiconductor material layer, for example, gallium nitride (GaN) doped with a second conductivity type dopant such as silicon (Si), germanium (Ge), and/or tin (Sn).

An electron blocking layer may be disposed between the first semiconductor layer SEM1 and the active layer MQW. The electron blocking layer may be a layer for suppressing or preventing too many electrons from flowing into the active layer MQW. For example, the electron blocking layer may be aluminum gallium nitride (AlGaN) and/or p-AlGaN doped with p-type Mg. The electron blocking layer can be omitted.

A superlattice layer may be disposed between the active layer MQW and the second semiconductor layer SEM2. The superlattice layer may be a layer for relieving stress between the second semiconductor layer SEM2 and the active layer MQW. For example, the superlattice layer may be made of indium gallium nitride (InGaN) and/or gallium nitride (GaN). The superlattice layer can be omitted.

Light extraction patterns LEP may be formed on an upper surface of the semiconductor stack STC. For example, the light extraction patterns LEP may be formed on an upper surface of the second semiconductor layer SEM2.

The light extraction patterns LEP may be patterns for increasing the efficiency of light output from an upper surface of a light emitting element LE. The light extraction patterns LEP may be concave patterns formed as hemispheres or semi-ellipsoids. The light extraction patterns LEP may be concave patterns having a semicircular or semielliptical cross-sectional shape. A maximum length Lmax of each light extraction pattern LEP in the third direction DR3 may be about 100 nm. In addition, a distance between adjacent light extraction patterns LEP may be about 100 nm or less.

The light extraction patterns LEP may be made of an organic layer such as acryl resin, epoxy resin, phenolic resin, polyamide resin, and/or polyimide resin. Alternatively, the light extraction patterns LEP may be made of an inorganic layer, for example, silicon nitride (SiNₓ), silicon oxynitride (SiON), silicon oxide (SiOₓ), titanium oxide (TiOₓ), and/or aluminum oxide (AlOₓ).

The protective layer INS may be a layer for protecting lower and side surfaces (e.g., outer peripheral surfaces) of a light emitting element LE. The protective layer INS may be disposed on lower and side surfaces of the conductive layer E1 and side surfaces of the semiconductor stack STC. Specifically, the protective layer INS may be disposed on the lower and side surfaces of the conductive layer E1, side surfaces of the first semiconductor layer SEM1, side surfaces of the active layer MQW, and side surfaces of the second semiconductor layer SEM2. The protective layer INS may be made of an inorganic layer, for example, silicon nitride (SiNₓ), silicon oxynitride (SiON), silicon oxide (SiOₓ), titanium oxide (TiOₓ), and/or aluminum oxide (AlOₓ).

A plurality of contact electrodes CTE may be disposed on the protective layer INS. Each of the contact electrodes CTE may be disposed between the first organic layer 210 and the protective layer INS. Each of the contact electrodes CTE may contact the first organic layer 210.

Although the contact electrodes CTE of each of the light emitting elements LE are disposed on the first organic layer 210 in FIGS. 6 and 7, the present disclosure is not limited thereto. For example, the first organic layer 210 may be disposed on a lower surface and a portion of a side surface of each contact electrode CTE of each of the light emitting elements LE. Alternatively, the first organic layer 210 may be disposed on the side surfaces of the conductive layer E1 of each of the light emitting elements LE. Alternatively, the first organic layer 210 may be disposed on the side surfaces of the first semiconductor layer SEM1, the side surfaces of the active layer MQW, and the side surfaces of the second semiconductor layer SEM2 of each of the light emitting elements LE. In this case, the first organic layer 210 may be disposed on a portion of each side surface of the second semiconductor layer SEM2.

Each of the contact electrodes CTE may be connected to the conductive layer E1 exposed without being covered by the protective layer INS. Accordingly, even if any one of the contact electrodes CTE is not connected to the conductive layer E1 due to a process error, the other contact electrode CTE may be connected to the conductive layer E1, thereby preventing a light emitting element LE from being not lighted up.

When the contact electrodes CTE are made of a metal with high reflectivity, light travelling in a lateral direction of the light emitting element LE from among light emitted from the active layer MQW of the light emitting element LE may be reflected by the contact electrodes CTE to exit from the upper surface of the light emitting element LE. Accordingly, a loss of light of the light emitting element LE can be reduced, and thus the light efficiency of the light emitting element LE can be increased. Therefore, in order to increase the light efficiency of the light emitting element LE, each of the contact electrodes CTE may cover most of the side surfaces (e.g., outer peripheral surfaces) of the semiconductor stack STC.

The contact electrodes CTE may include molybdenum (Mo), aluminum (Al), chromium (Cr), gold (Au), titanium (Ti), nickel (Ni), neodymium (Nd), and/or copper (Cu). Specifically, to increase reflectivity, the contact electrodes CTE may have a two-layer structure of chromium (Cr) and gold (Au), a three-layer structure of titanium (Ti), aluminum (Al) and titanium (Ti), or a three-layer structure of indium tin oxide (ITO), silver (Ag) and indium tin oxide (ITO). Alternatively, the contact electrodes CTE may be consist of a transparent conductive material (or a transparent conductive oxide (TCO) such as indium tin oxide (ITO) and indium zinc oxide (IZO). The contact electrodes CTE may be consist of a two-layer structure or a three-layer structure of transparent conductive materials (or transparent conductive oxides (TCO)).

The contact electrodes CTE may be disposed on the side surfaces (e.g., outer peripheral surfaces) of the semiconductor stack STC, respectively. In the side surfaces of the semiconductor stack STC, an area adjacent to the upper surface of the semiconductor stack STC may be covered by the protective layer INS, but may be exposed without being covered by the contact electrodes CTE. For example, a distance DS1 between the upper surface of the semiconductor stack STC and each contact electrode CTE in the third direction DR3 may be greater than about 100 nm. In addition, the distance DS1 between the upper surface of the semiconductor stack STC and each contact electrode CTE in the third direction DR3 may be greater than the maximum length Lmax of each light extraction pattern LEP in the third direction DR3. Here, the third direction DR3 may be substantially the same as a height direction (or thickness direction) of the light emitting element LE. When the contact electrodes CTE are spaced (e.g., spaced apart) from the upper surface of the semiconductor stack STC as described above, the contact electrodes CTE can be prevented from being peeled off by a chemical solution or the like during a manufacturing process, unlike when exposed on the upper surface of the semiconductor stack STC.

Connection electrodes BE connect the contact electrodes CTE of each light emitting element LE to a pixel electrode PXE1/PXE2/PXE3. The connection electrodes BE may be connected to the pixel electrode PXE1/PXE2/PXE3 exposed through connection holes BH penetrating the first organic layer 210. In addition, the connection electrodes BE may be disposed on an upper surface of the first organic layer 210 and the contact electrodes CTE.

The connection electrodes BE may include molybdenum (Mo), aluminum (Al), chromium (Cr), gold (Au), titanium (Ti), nickel (Ni), neodymium (Nd), and/or copper (Cu). Alternatively, the connection electrodes BE may be made of a transparent conductive material (TCO) such as indium tin oxide (ITO) and/or indium zinc oxide (IZO).

The connection electrodes BE may be disposed on the side surfaces (e.g., outer peripheral surfaces) of the semiconductor stack STC. In the side surfaces of the semiconductor stack STC, an area adjacent to the upper surface of the semiconductor stack STC may be exposed without being covered by the connection electrodes BE. For example, a distance DS2 between the upper surface of the semiconductor stack STC and each connection electrode BE in the third direction DR3 may be greater than about 100 nm. In addition, the distance DS2 between the upper surface of the semiconductor stack STC and each connection electrode BE in the third direction DR3 ay be greater than the maximum length Lmax of each light extraction pattern LEP in the third direction DR3.

The distance DS2 between the upper surface of the semiconductor stack STC and each connection electrode BE in the third direction DR3 may be greater than the distance DS1 between the upper surface of the semiconductor stack STC and each contact electrode CTE in the third direction DR3, but the present disclosure is not limited thereto. For example, the distance DS2 between the upper surface of the semiconductor stack STC and each connection electrode BE in the third direction DR3 may be smaller than the distance DS1 between the upper surface of the semiconductor stack STC and each contact electrode CTE in the third direction DR3. In this case, the connection electrodes BE may cover at least a portion of the protective layer INS exposed without being covered by the contact electrodes CTE. Alternatively, the connection electrodes BE may cover the whole of the protective layer INS exposed without being covered by the contact electrodes CTE. For another example, the distance DS2 between the upper surface of the semiconductor stack STC and each connection electrode BE in the third direction DR3 may be substantially equal to the distance DS1 between the upper surface of the semiconductor stack STC and each contact electrode CTE in the third direction DR3.

A second organic layer 211 may cover a portion of the side surfaces of each of the light emitting elements LE. In addition, the second organic layer 211 may cover the connection electrodes BE and may be disposed on the first organic layer 210.

A third organic layer 212 may be disposed on the second organic layer 211. The third organic layer 212 may cover another portion of the side surfaces of each of the light emitting elements LE. The third organic layer 212 may be disposed on the protective layer INS, the contact electrodes CTE, and the connection electrodes BE exposed without being covered by the second organic layer 211 as illustrated in FIG. 7, but the present disclosure is not limited thereto. For example, the entire connection electrodes BE may be covered by the second organic layer 211. The upper surface of each of the light emitting elements LE may be exposed without being covered by the third organic layer 212.

The second organic layer 211 and the third organic layer 212 are layers for flattening steps caused by the light emitting elements LE. If the second organic layer 211 is high enough to cover most of the side surfaces of each of the light emitting elements LE, the third organic layer 212 may be omitted.

The second organic layer 211 and the third organic layer 212 may be made of an organic layer such as acryl resin, epoxy resin, phenolic resin, polyamide resin, and/or polyimide resin.

The common electrode CE may be disposed on the upper surface of each of the light emitting elements LE and an upper surface of the third organic layer 212. The common electrode CE may be a common layer commonly formed in a first subpixel SPX1, a second subpixel SPX2, and a third subpixel SPX3. The common electrode CE may be made of a transparent conductive material (TCO) that can transmit light, such as indium tin oxide (ITO) and/or indium zinc oxide (IZO).

The pixel electrodes PXE1 through PXE3 may be referred to as anodes or first electrodes, and the common electrode CE may be referred to as a cathode or a second electrode.

A first capping layer CAP1 may be disposed on the common electrode CE.

A light blocking layer BM, a first light conversion layer QDL1, a second light conversion layer QDL2, and a light transmission layer TPL may be disposed on the first capping layer CAP1. The first light conversion layer QDL1, the second light conversion layer QDL2, and the light transmission layer TPL may be separated by the light blocking layer BM. Therefore, the first light conversion layer QDL1 may be disposed on the first capping layer CAP1 in the first subpixel SPX1, the second light conversion layer QDL2 may be disposed on the first capping layer CAP1 in the second subpixel SPX2, and the light transmission layer TPL may be disposed on the first capping layer CAP1 in the third subpixel SPX3. The light blocking layer BM may not overlap the light emitting elements LE in the third direction DR3.

The first light conversion layer QDL1 may convert a portion of third light (light in the blue wavelength band) incident from a light emitting element LE into first light (light in the red wavelength band). The first light conversion layer QDL1 may include a first base resin BRS1 and first wavelength conversion particles WCP1. The first base resin BRS1 may include a light-transmitting organic material. The first wavelength conversion particles WCP1 may convert a portion of the third light (light in the blue wavelength band) incident from the light emitting element LE into the first light (light in the red wavelength band).

The second light conversion layer QDL2 may convert a portion of third light (light in the blue wavelength band) incident from a light emitting element LE into second light (light in the green wavelength band). The second light conversion layer QDL2 may include a second base resin BRS2 and second wavelength conversion particles WCP2. The second base resin BRS2 may include a light-transmitting organic material. The second wavelength conversion particles WCP2 may convert a portion of the third light (light in the blue wavelength band) incident from the light emitting element LE into the second light (light in the green wavelength band).

The light transmission layer TPL may include a light-transmitting organic material.

For example, the first base resin BRS1, the second base resin BRS2, and the light transmission layer TPL may include epoxy resin, acrylic resin, cardo resin, and/or imide resin. The first and second wavelength conversion particles WCP1 and WCP2 may be quantum dots, quantum rods, fluorescent materials, and/or phosphorescent materials.

The light blocking layer BM may include a first light blocking layer BM1 and a second light blocking layer BM2 stacked sequentially. A length of the first light blocking layer BM1 in the first direction DR1 or a length of the first light blocking layer BM1 in the second direction DR2 may be greater than a length of the second light blocking layer BM2 in the first direction DR1 or a length of the second light blocking layer BM2 in the second direction DR2. The first light blocking layer BM1 and the second light blocking layer BM2 may be made of an organic layer such as acryl resin, epoxy resin, phenolic resin, polyamide resin, and/or polyimide resin. The first light blocking layer BM1 and the second light blocking layer BM2 may include a light blocking material to prevent light of a light emitting element LE of any one subpixel from travelling to a neighboring subpixel. For example, the first light blocking layer BM1 and the second light blocking layer BM2 may include an inorganic black pigment such as carbon black and/or an organic black pigment.

A second capping layer CAP2 may be disposed on the first capping layer CAP1 and the light blocking layer BM. The second capping layer CAP2 may be disposed on side and upper surfaces of the light blocking layer BM. That is, the second capping layer CAP2 may be disposed on side surfaces of the first light blocking layer BM1 and side and upper surfaces of the second light blocking layer BM2.

A reflective layer RF may be disposed between the light blocking layer BM and the first light conversion layer QDL1, between the light blocking layer BM and the second light conversion layer QDL2, and between the light blocking layer BM and the light transmission layer TPL. The reflective layer RF may be disposed on the second capping layer CAP2 disposed on the side surfaces of the first light blocking layer BM1 and the side surfaces of the second light blocking layer BM2. The reflective layer RF may reflect light travelling in the lateral direction from the first light conversion layer QDL1, the second light conversion layer QDL2, and the light transmission layer TPL.

The reflective layer RF may include a metal material with high reflectivity, such as aluminum (Al). A thickness of the reflective layer RF may be about 0.1 μm.

Alternatively, to serve as distributed Bragg reflectors, the reflective layer RF may include M (M is an integer of 2 or more) pairs of first and second layers having different refractive indices. In this case, M first layers and M second layers may be arranged alternately. The first and second layers may be made of an inorganic layer, for example, silicon nitride (SiNₓ), silicon oxynitride (SiON), silicon oxide (SiOₓ), titanium oxide (TiOₓ), and/or aluminum oxide (AlOₓ).

A third capping layer CAP3 may be disposed on the reflective layer RF, the second capping layer CAP2, the first light conversion layer QDL1, the second light conversion layer QDL2, and the light transmission layer TPL.

The first capping layer CAP1, the second capping layer CAP2, and the third capping layer CAP3 may be made of an inorganic layer, for example, silicon nitride (SiNₓ), silicon oxynitride (SiON), silicon oxide (SiOₓ), titanium oxide (TiOₓ), and/or aluminum oxide (AlOₓ). The first light conversion layer QDL1, the second light conversion layer QDL2, and the light transmission layer TPL may be encapsulated by the first capping layer CAP1, the second capping layer CAP2, and the third capping layer CAP3.

A fourth organic layer 213 may be disposed on the third capping layer CAP3. A plurality of color filters CF1 through CF3 may be disposed on the fourth organic layer 213. The color filters CF1 through CF3 may include first color filters CF1, second color filters CF2, and third color filters CF3.

A first color filter CF1 disposed in the first subpixel SPX1 may transmit first light (light in the red wavelength band) and absorb or block third light (light in the blue wavelength band). Therefore, the first color filter CF1 may transmit the first light (light in the red wavelength band), which has been converted by the first light conversion layer QDL1 from a portion of the third light (light in the blue wavelength band) emitted from a light emitting element LE, and may absorb or block the third light (light in the blue wavelength band) which has not been converted by the first light conversion layer QDL1. Accordingly, the first subpixel SPX1 may output the first light (light in the red wavelength band).

A second color filter CF2 disposed in the second subpixel SPX2 may transmit second light (light in the green wavelength band) and absorb or block third light (light in the blue wavelength band). Therefore, the second color filter CF2 may transmit the second light (light in the green wavelength band), which has been converted by the second light conversion layer QDL2 from a portion of the third light (light in the blue wavelength band) emitted from a light emitting element LE, and may absorb or block the third light (light in the blue wavelength band) which has not been converted by the second light conversion layer QDL2. Accordingly, the second subpixel SPX2 may output the second light (light in the green wavelength band).

A third color filter CF3 disposed in the third subpixel SPX3 may transmit third light (light in the blue wavelength band). Therefore, the third color filter CF3 may transmit the third light (light in the blue wavelength band) that passes through the light transmission layer TPL after being emitted from a light emitting element LE. Accordingly, the third subpixel SPX3 may emit the third light (light in the blue wavelength band).

The first color filter CF1, the second color filter CF2, and the third color filter CF3 overlapping each other in the third direction DR3 may overlap the light blocking layer BM in the third direction DR3.

A fifth organic layer 214 for planarization may be disposed on the color filters CF1 through CF3

The fourth organic layer 213 and the fifth organic layer 214 may be made of acryl resin, epoxy resin, phenolic resin, polyamide resin, and/or polyimide resin.

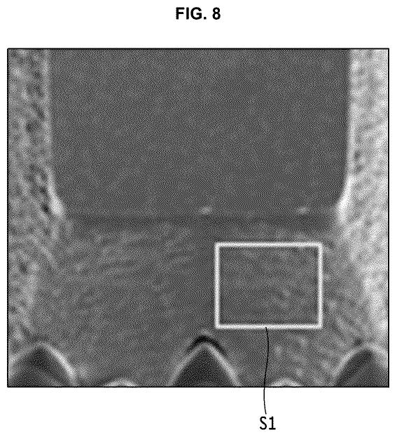

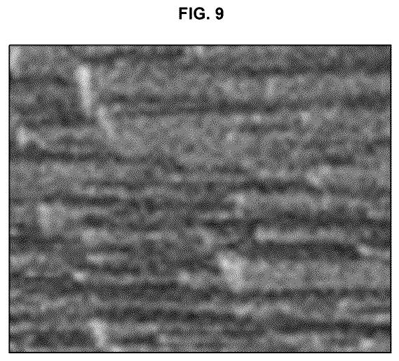

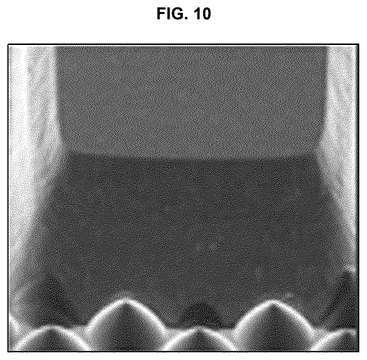

FIG. 8 is an image of a first side area INS1. FIG. 9 is an enlarged image of area S1 of the first side area INS1. FIG. 10 is an image of a second side area INS2.

Referring to FIGS. 7 through 10, the protective layer INS includes the first side area INS1 exposed without being covered by the contact electrodes CTE and the second side area INS2 covered by the contact electrodes CTE. Because the first side area INS1 is exposed without being covered by the contact electrodes CTE, it is exposed to an etchant. On the other hand, because the second side area INS2 is covered by the contact electrodes CTE, it is not exposed to the etchant. Accordingly, surface roughness of the first side area INS1 may be greater than that of the second side area INS2, as shown in FIGS. 8 through 10. That is, a surface of the second side area INS2 may be smoother than a surface of the first side area INS1.

In summary, the surface of the first side area INS1 may be formed to have irregularities instead of being smooth, thereby increasing the efficiency of light output from the first side area INS1 of a light emitting element LE.

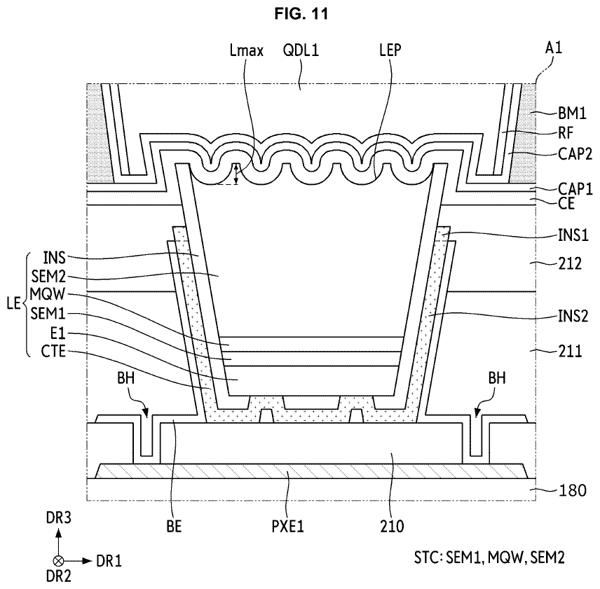

FIG. 11 is a detailed cross-sectional view of another example of the area A1 of FIG. 6.

The embodiment of FIG. 11 is different from the embodiment of FIG. 7 in that a light emitting element LE includes one contact electrode CTE rather than a plurality of contact electrodes CTE. In FIG. 11, descriptions overlapping those of the embodiment of FIG. 7 will be omitted, and differences from the embodiment of FIG. 7 will be mainly described.

Referring to FIG. 11, a plurality of areas of a conductive layer E1 may be exposed without being covered by a protective layer INS. The embodiment of FIG. 11 is different from the embodiment of FIG. 7 in that a light emitting element LE includes one contact electrode CTE rather than a plurality of contact electrodes CTE. The contact electrode CTE may be connected to the conductive layer E1 in each of the areas of the conductive layer E1. Accordingly, even if the contact electrode CTE is not connected to the conductive layer E1 in any one of the areas due to a process error, it may be connected to the conductive layer E1 in the other areas, thereby preventing the light emitting element LE from being not lighted up.

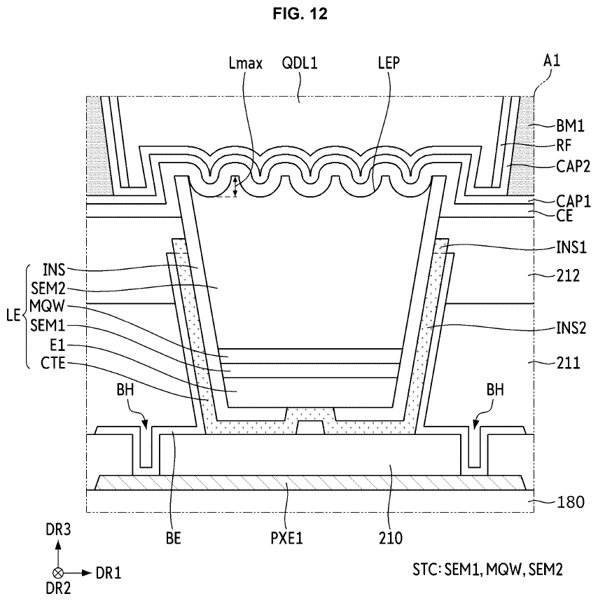

FIG. 12 is a detailed cross-sectional view of another example of the area A1 of FIG. 6.

The embodiment of FIG. 12 is different from the embodiment of FIG. 7 in that a light emitting element LE includes one contact electrode CTE rather than a plurality of contact electrodes CTE. In FIG. 12, descriptions overlapping those of the embodiment of FIG. 7 will be omitted, and differences from the embodiment of FIG. 7 will be mainly described.

Referring to FIG. 12, a portion of a conductive layer E1 may be exposed without being covered by a protective layer INS. The contact electrode CTE may be connected to the portion of the conductive layer E1 which is exposed without being covered by the protective layer INS.

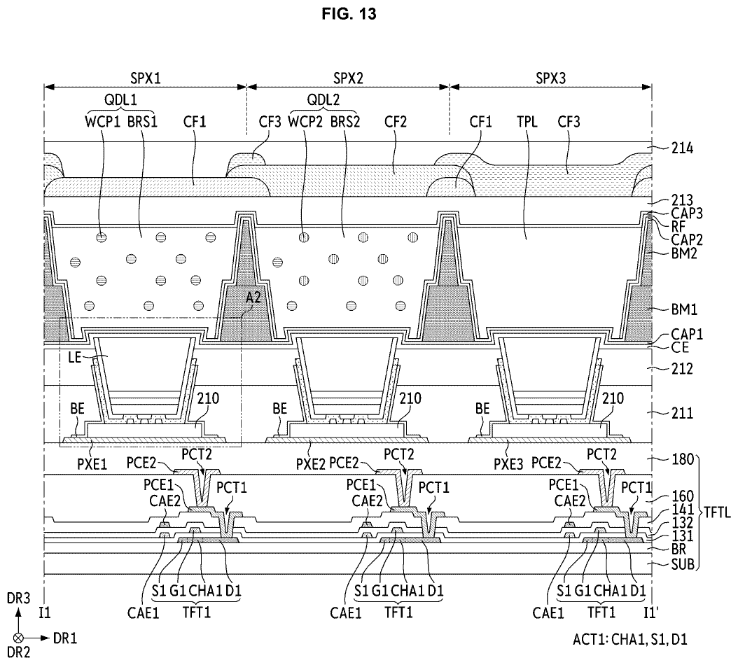

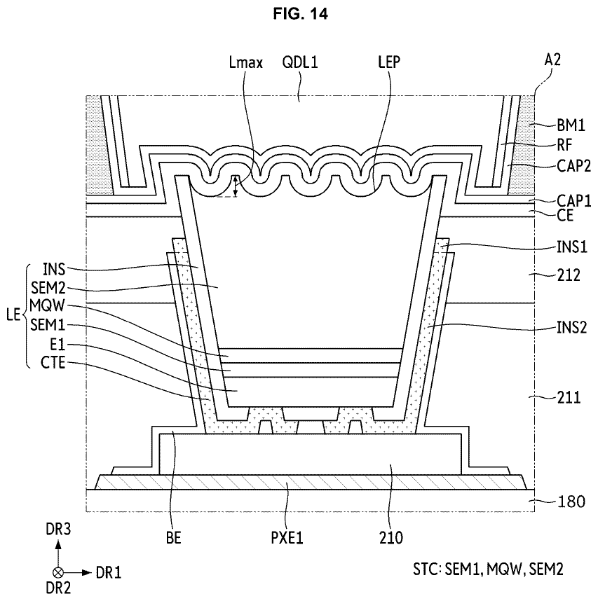

FIG. 13 is a cross-sectional view illustrating another example of the cross section of the display panel corresponding to the line I1-I1′ of FIG. 5. FIG. 14 is a detailed cross-sectional view of an example of an area A2 of FIG. 13.

The embodiment of FIGS. 13 and 14 is different from the embodiment of FIGS. 6 and 7 in that each organic layer 210 is disposed on a portion of an upper surface of a pixel electrode PXE1/PXE2/PXE3. In FIGS. 13 and 14, descriptions overlapping those of the embodiment of FIGS. 6 and 7 will be omitted, and differences from the embodiment of FIGS. 6 and 7 will be mainly described.

Referring to FIGS. 13 and 14, because each organic layer 210 is disposed on a portion of the upper surface of a pixel electrode PXE1/PXE2/PXE3, there is no need to form a connection hole BH for exposing the pixel electrode PXE1/PXE2/PXE3. Connection electrodes BE may be disposed on a portion of the upper surface of the pixel electrode PXE1/PXE2/PXE3 which is not covered by the organic layer 210. The connection electrodes BE may be disposed on upper and side surfaces of the organic layer 210.

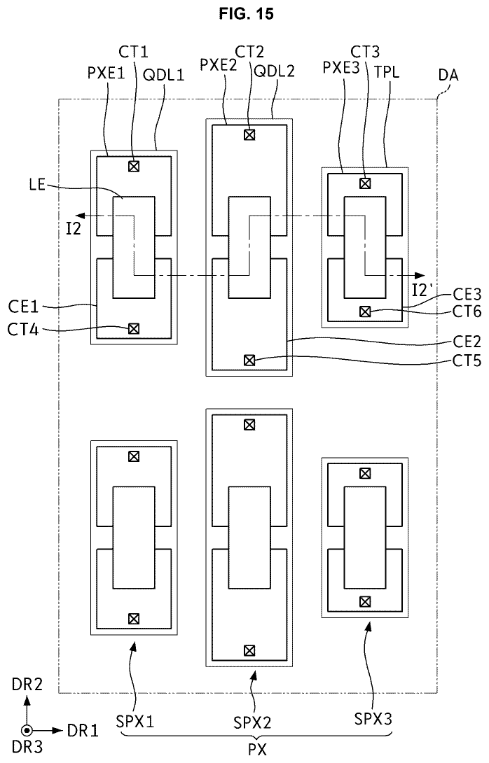

FIG. 15 is a layout view illustrating pixels of a display area according to one or more embodiments.

The embodiment of FIG. 15 is different from the embodiment of FIG. 5 in that a light emitting element LE is disposed on a pixel electrode PXE1/PXE2/PXE3 and a common electrode CE1/CE2/CE3 in each of a first subpixel SPX1, a second subpixel SPX2, and a third subpixel SPX3. In FIG. 15, descriptions overlapping those of the embodiment of FIG. 5 will be omitted, and differences from the embodiment of FIG. 5 will be mainly described.

Referring to FIG. 15, the pixel electrode PXE1/PXE2/PXE3 and the common electrode CE1/CE2/CE3 may be arranged along the second direction DR2 in each of the first subpixel SPX1, the second subpixel SPX2, and the third subpixel SPX3. Each of the pixel electrodes PXE1 through PXE3 and the common electrodes CE1 through CE3 may have a rectangular planar shape, but the present disclosure is not limited thereto. The area of a first pixel electrode PXE1 may be equal to the area of a first common electrode CE1, the area of a second pixel electrode PXE2 may be equal to the area of a second common electrode CE2, and the area of a third pixel electrode PXE3 may be equal to the area of a third common electrode CE3, but the present disclosure is not limited thereto.

When the light conversion efficiency of a second light conversion layer QDL2 is lower than the light conversion efficiency of a first light conversion layer QDL1, the area of the second pixel electrode PXE2 may be larger than the area of the first pixel electrode PXE1, and the area of the second common electrode CE2 may be larger than the area of the first common electrode CE1. In addition, because the first light conversion layer QDL1 must convert light whereas a light transmission layer TPL transmits light of a light emitting element LE as it is, the area of the first pixel electrode PXE1 may be larger than the area of the third pixel electrode PXE3, and the area of the first common electrode CE1 may be larger than the area of the third common electrode CE3.

The first common electrode CE1 may be connected to a second power line VSL, to which the second power supply voltage VSS is applied, through a first common connection hole CT4. The second common electrode CE2 may be connected to the second power line VSL through a second common connection hole CT5. The third common electrode CE3 may be connected to the second power line VSL through a third common connection hole CT6. Therefore, the second power supply voltage VSS may be applied to each of the common electrodes CE1 through CE3.

In each of the first subpixel SPX1, the second subpixel SPX2, and the third subpixel SPX3, a light emitting element LE is disposed on the pixel electrode PXE1/PXE2/PXE3 and the common electrode CE1/CE2/CE3. Therefore, a length of the light emitting element LE in the second direction DR2 may be greater than a length of the light emitting element LE in the first direction DR1.

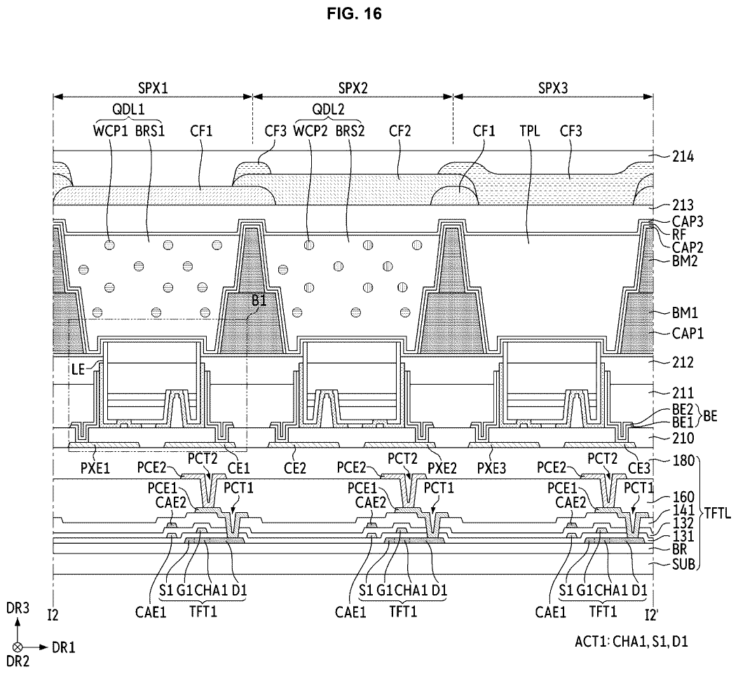

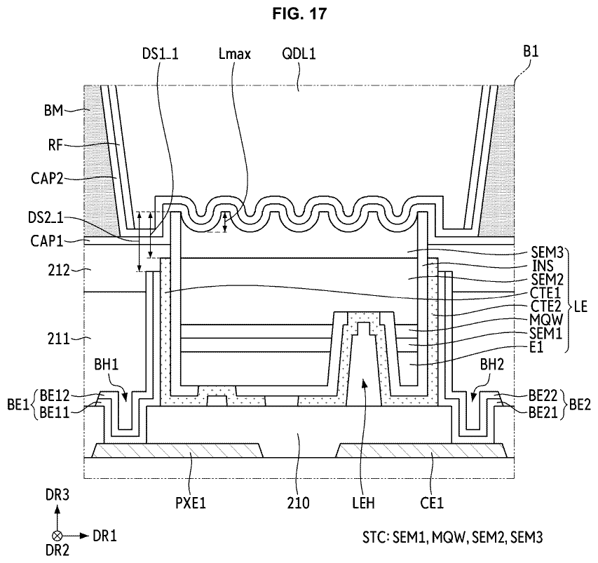

FIG. 16 is a cross-sectional view illustrating an example of a cross section of a display panel corresponding to the line I2-I2′ of FIG. 15. FIG. 17 is a detailed cross-sectional view of an example of an area B1 of FIG. 16.

The embodiment of FIGS. 16 and 17 is different from the embodiment of FIGS. 6 and 7 in that each light emitting element LE is a flip-type micro-LED. In FIGS. 16 and 17, descriptions overlapping those of the embodiment of FIGS. 6 and 7 will be omitted, and differences from the embodiment of FIGS. 6 and 7 will be mainly described.

Referring to FIGS. 16 and 17, a pixel electrode layer including pixel electrodes PXE1 through PXE3 and common electrodes CE1 through CE3 may be disposed on a second planarization organic layer 180.

Each light emitting element LE may be a flip-type micro-LED. The flip-type micro-LED refers to an LED in which contact electrodes CTE1 and CTE2 are formed on a surface (e.g., a lower surface) of a light emitting element LE.

A semiconductor stack STC of each light emitting element LE may further include a third semiconductor layer SEM3. The third semiconductor layer SEM3 is a semiconductor material layer whose n-type dopant is lower than a suitable threshold value (e.g., predetermined threshold value) and may be referred to as an un-doped semiconductor layer. For example, the third semiconductor layer SEM3 may be indium aluminum gallium nitride (InAlGaN), gallium nitride (GaN), aluminum gallium nitride (AlGaN), indium gallium nitride (InGaN), aluminum nitride (AlN), and/or indium nitride InN) whose n-type dopant is lower than a suitable threshold value (e.g., predetermined threshold value).

The third semiconductor layer SEM3 may be disposed on a second semiconductor layer SEM2. In this case, light extraction patterns LEP may be formed on an upper surface of the third semiconductor layer SEM3.

In FIG. 17, a protective layer INS is disposed on side surfaces of a first semiconductor layer SEM1, side surfaces of an active layer MQW, and side surfaces of the second semiconductor layer SEM2 of the semiconductor stack STC and is also disposed on side surfaces of the third semiconductor layer SEM3, but the present disclosure is not limited thereto. For example, the protective layer INS may be disposed on the side surfaces of the first semiconductor layer SEM1, the side surfaces of the active layer MQW, the side surfaces of the second semiconductor layer SEM2, and may not be disposed on the side surfaces of the third semiconductor layer SEM3 of the semiconductor stack STC.

A hole LEH may be formed to pass through a conductive layer E1, the first semiconductor layer SEM1, and the active layer MQW of each light emitting element LE and expose the second semiconductor layer SEM2. The hole LEH may have a circular planar shape, but the present disclosure is not limited thereto. For example, the hole LEH may have an elliptical planar shape or a polygonal planar shape such as a quadrangle.

In addition, the protective layer INS may be disposed on sidewalls of the conductive layer E1, sidewalls of the first semiconductor layer SEM1, and sidewalls of the active layer MQW exposed in the hole LEH. The protective layer INS may not cover the second semiconductor layer SEM2 in the hole LEH. Therefore, the second semiconductor layer SEM2 may be exposed without being covered by the protective layer INS.

A first contact electrode CTE1 may be disposed on at least one side surface of the semiconductor stack STC and at least one side surface and a lower surface of the conductive layer E1. The first contact electrode CTE1 may be disposed on a portion of the lower surface of the conductive layer E1 which is exposed without being covered by the protective layer INS. Therefore, the first contact electrode CTE1 may be electrically connected to the conductive layer E1.

A second contact electrode CTE2 may be disposed on at least one side surface of the semiconductor stack STC and at least one side surface and the lower surface of the conductive layer E1. Here, while the first contact electrode CTE1 is disposed on a first side surface of the semiconductor stack STC and a first side surface of the conductive layer E1, the second contact electrode CTE2 may be disposed on a second side surface of the semiconductor stack STC and a second side surface of the conductive layer E1.

The second contact electrode CTE2 may be disposed on the protective layer INS disposed in the hole LEH and the second semiconductor layer SEM2 exposed in the hole LEH without being covered by the protective layer INS. Therefore, the second contact electrode CTE2 may be electrically connected to the second semiconductor layer SEM2 in the hole LEH.

In FIGS. 16 and 17, the first contact electrode CTE1 and the second contact electrode CTE2 of each light emitting element LE are disposed on a first organic layer 210, but the present disclosure is not limited thereto. For example, the first organic layer 210 may be disposed on a lower surface and a portion of a side surface of the first contact electrode CTE1 and a lower surface and a portion of a side surface of the second contact electrode CTE1 of each light emitting element LE. Alternatively, the first organic layer 210 may be disposed on the side surfaces of the conductive layer E1 of each light emitting element LE. Alternatively, the first organic layer 210 may be disposed on the side surfaces of the first semiconductor layer SEM1, the side surfaces of the active layer MQW, and the side surfaces of the second semiconductor layer SEM2 of each light emitting element LE. In this case, the first organic layer 210 may be disposed on a portion of each side surface of the second semiconductor layer SEM2.

In each side surface of the semiconductor stack STC, an area adjacent to an upper surface of the semiconductor stack STC may be covered by the protective layer INS, but may be exposed without being covered by the first contact electrode CTE1 or the second contact electrode CTE2. For example, a distance DS1_1 between the upper surface of the semiconductor stack STC and the first contact electrode CTE1 in the third direction DR3 may be greater than about 100 nm. In addition, the distance DS1_1 between the upper surface of the semiconductor stack STC and the first contact electrode CTE1 in the third direction DR3 may be greater than a maximum length Lmax of each light extraction pattern in the third direction DR3. When the first contact electrode CTE1 is spaced (e.g., spaced apart) from the upper surface of the semiconductor stack STC as described above, it can be prevented from being peeled off by a chemical solution or the like during a manufacturing process, unlike when exposed on the upper surface of the semiconductor stack STC.

In addition, a distance DS1_1 between the upper surface of the semiconductor stack STC and the second contact electrode CTE2 in the third direction DR3 may be greater than about 100 nm. In addition, the distance DS1_1 between the upper surface of the semiconductor stack STC and the second contact electrode CTE2 in the third direction DR3 may be greater than the maximum length Lmax of each light extraction pattern in the third direction DR3. When the second contact electrode CTE2 is spaced (e.g., spaced apart) from the upper surface of the semiconductor stack STC as described above, it can be prevented from being peeled off by a chemical solution or the like during a manufacturing process, unlike when exposed on the upper surface of the semiconductor stack STC.

Each of the first contact electrode CTE1 and the second contact electrode CTE2 may be disposed on three side surfaces of the semiconductor stack STC. For example, when the semiconductor stack STC includes first through fourth side surfaces, the first contact electrode CTE1 may be disposed on the first side surface, the second side surface and the third side surface, and the second contact electrode CTE2 may be disposed on the second side surface, the third side surface and the fourth side surface.

A first connection electrode BE1 connects the first contact electrode CTE1 of each light emitting element LE to a pixel electrode PXE1/PXE2/PXE3. The first connection electrode BE1 may be connected to the pixel electrode PXE1/PXE2/PXE3 exposed through a first connection hole BH1 penetrating the first organic layer 210. In addition, the first connection electrode BE1 may be disposed on an upper surface of the first organic layer 210 and the first contact electrode CTE1.

The first connection electrode BE1 may include a first sub-connection electrode BE11 and a second sub-connection electrode BE12 disposed on the first sub-connection electrode BE11. The first sub-connection electrode BE11 and the second sub-connection electrode BE12 may include the same material or different materials. Each of the first sub-connection electrode BE11 and the second sub-connection electrode BE12 may include molybdenum (Mo), aluminum (Al), chromium (Cr), gold (Au), titanium (Ti), nickel (Ni), neodymium (Nd), and/or copper (Cu). Alternatively, each of the first sub-connection electrode BE11 and the second sub-connection electrode BE12 may be made of a transparent conductive material (TCO) such as indium tin oxide (ITO) and/or indium zinc oxide (IZO).

A second connection electrode BE2 connects the second contact electrode CTE2 of each light emitting element LE to a common electrode CE1/CE2/CE3. The second connection electrode BE2 may be connected to the common electrode CE1/CE2/CE3 exposed through a second connection hole BH2 penetrating the first organic layer 210. In addition, the second connection electrode BE2 may be disposed on the upper surface of the first organic layer 210 and the second contact electrode CTE2.

The second connection electrode BE2 may include a third sub-connection electrode BE21 and a fourth sub-connection electrode BE22 disposed on the third sub-connection electrode BE21. The third sub-connection electrode BE21 and the fourth sub-connection electrode BE22 may include the same material or different materials. Each of the third sub-connection electrode BE21 and the fourth sub-connection electrode BE22 may include molybdenum (Mo), aluminum (Al), chromium (Cr), gold (Au), titanium (Ti), nickel (Ni), neodymium (Nd), and/or copper (Cu). Alternatively, each of the third sub-connection electrode BE21 and the fourth sub-connection electrode BE22 may be made of a transparent conductive material (TCO) such as indium tin oxide (ITO) and/or indium zinc oxide (IZO).

As illustrated in FIGS. 16 and 17, the conductive layer E1 of each light emitting element LE may be connected to a pixel electrode PXE1/PXE2/PXE3 through the first contact electrode CTE1 and the first connection electrode BE1. In addition, the second semiconductor layer SEM2 of each light emitting element LE may be connected to a common electrodes CE1/CE2/CE3 through the second contact electrode CTE2 formed in the hole LEH and the second connection electrode BE2.

In addition, in each side surface of the semiconductor stack STC, an area adjacent to the upper surface of the semiconductor stack STC may be exposed without being covered by the first connection electrode BE1 or the second connection electrode BE2. For example, a distance DS2_1 between the upper surface of the semiconductor stack STC and the first connection electrode BE1 in the third direction DR3 may be greater than about 100 nm. In addition, the distance DS2_1 between the upper surface of the semiconductor stack STC and the first connection electrode BE1 in the third direction DR3 may be greater than the maximum length Lmax of each light extraction pattern in the third direction DR3. When the first connection electrode BE1 is spaced (e.g., spaced apart) from the upper surface of the semiconductor stack STC as described above, it can be prevented from being peeled off by a chemical solution or the like during a manufacturing process, unlike when exposed on the upper surface of the semiconductor stack STC.

In addition, the distance DS2_1 between the upper surface of the semiconductor stack STC and the first connection electrode BE1 in the third direction DR3 may be greater than the distance DS1_1 between the upper surface of the semiconductor stack STC and the first contact electrode CTE1 in the third direction DR3. However, the present disclosure is not limited thereto. For example, the distance DS2_1 between the upper surface of the semiconductor stack STC and the first connection electrode BE1 in the third direction DR3 may be smaller than the distance DS1_1 between the upper surface of the semiconductor stack STC and the first contact electrode CTE1 in the third direction DR3. In this case, the first connection electrode BE1 may cover at least a portion of the protective layer INS which is exposed without being covered by the first contact electrode CTE1. Alternatively, the first connection electrode BE1 may cover the whole of the protective layer INS exposed without being covered by the first contact electrode CTE1. For another example, the distance DS2_1 between the upper surface of the semiconductor stack STC and the first connection electrode BE1 in the third direction DR3 may be substantially equal to the distance DS1_1 between the upper surface of the semiconductor stack STC and the first contact electrode CTE1 in the third direction DR3.

In addition, a distance DS2_1 between the upper surface of the semiconductor stack STC and the second connection electrode BE2 in the third direction DR3 may be greater than about 100 nm. In addition, the distance DS2_1 between the upper surface of the semiconductor stack STC and the second connection electrode BE2 in the third direction DR3 may be greater than the maximum length Lmax of each light extraction pattern in the third direction DR3. When the second connection electrode BE2 is spaced (e.g., spaced apart) from the upper surface of the semiconductor stack STC as described above, it can be prevented from being peeled off by a chemical solution or the like during a manufacturing process, unlike when exposed on the upper surface of the semiconductor stack STC.

In addition, the distance DS2_1 between the upper surface of the semiconductor stack STC and the second connection electrode BE2 in the third direction DR3 may be greater than the distance DS1_1 between the upper surface of the semiconductor stack STC and the second contact electrode CTE2 in the third direction DR3, but the present disclosure is not limited thereto. For example, the distance DS2_1 between the upper surface of the semiconductor stack STC and the second connection electrode BE2 in the third direction DR3 may be smaller than the distance DS1_1 between the upper surface of the semiconductor stack STC and the second contact electrode CTE2 in the third direction DR3. In this case, the second connection electrode BE2 may cover at least a portion of the protective layer INS which is exposed without being covered by the second contact electrode CTE2. Alternatively, the second connection electrode BE2 may cover the whole of the protective layer INS exposed without being covered by the second contact electrode CTE2. For another example, the distance DS2_1 between the upper surface of the semiconductor stack STC and the second connection electrode BE2 in the third direction DR3 may be substantially equal to the distance DS1_1 between the upper surface of the semiconductor stack STC and the second contact electrode CTE2 in the third direction DR3.

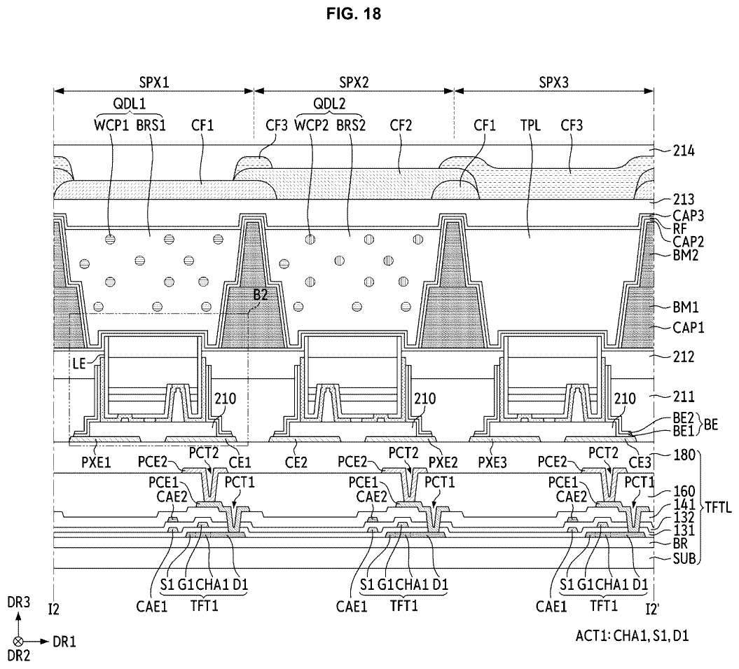

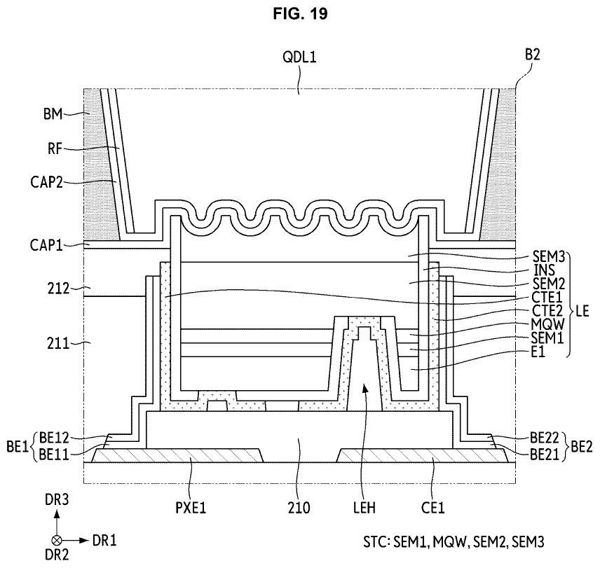

FIG. 18 is a cross-sectional view illustrating another example of the cross-section of the display panel corresponding to the line I2-I2′ of FIG. 15. FIG. 19 is a detailed cross-sectional view of another example of an area B2 of FIG. 18.

The embodiment of FIGS. 18 and 19 is different from the embodiment of FIGS. 16 and 17 in that each organic layer 210 is disposed on a portion of an upper surface of a pixel electrode PXE1/PXE2/PXE3 and a portion of an upper surface of a common electrode CE. In FIGS. 18 and 19, descriptions overlapping those of the embodiment of FIGS. 16 and 17 will be omitted, and differences from the embodiment of FIGS. 16 and 17 will be mainly described.

Referring to FIGS. 18 and 19, each organic layer 210 is disposed on a portion of the upper surface of the pixel electrode PXE1, PXE2, or PXE3 and a portion of the upper surface of the common electrode CE1, CE2, or CE3. Therefore, there is no need to form a first connection hole BH1 for exposing each of the pixel electrodes PXE1 through PXE3 and a second connection hole BH2 for exposing each of the common electrodes CE1 through CE3.

Each first connection electrode BE1 may be disposed on a portion of the upper surface of the pixel electrode PXE1/PXE2/PXE3 which is not covered by an organic layer 210. Each second connection electrode BE2 may be disposed on a portion of the upper surface of the common electrode CE1/CE2/CE3 which is not covered by the organic layer 210. In addition, each of the first and second connection electrodes BE1 and BE2 may be disposed on an upper surface and at least one side surface of the organic layer 210.

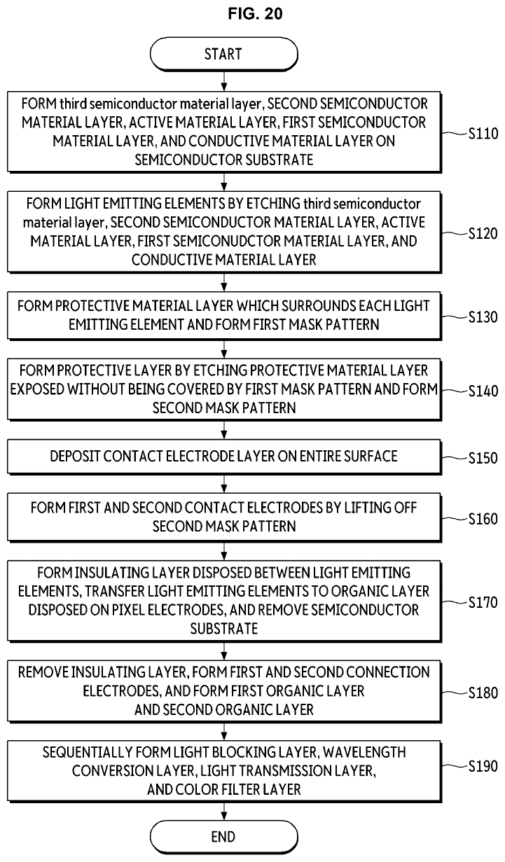

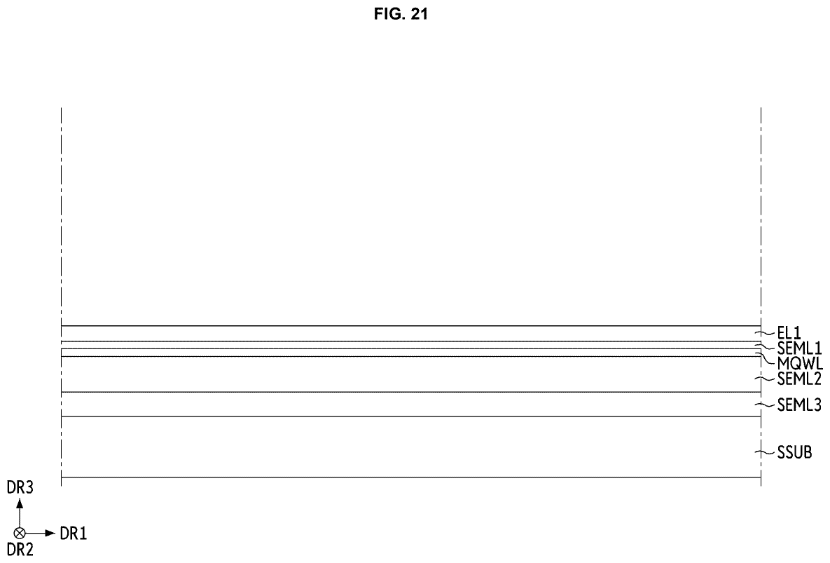

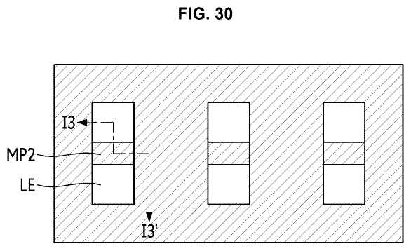

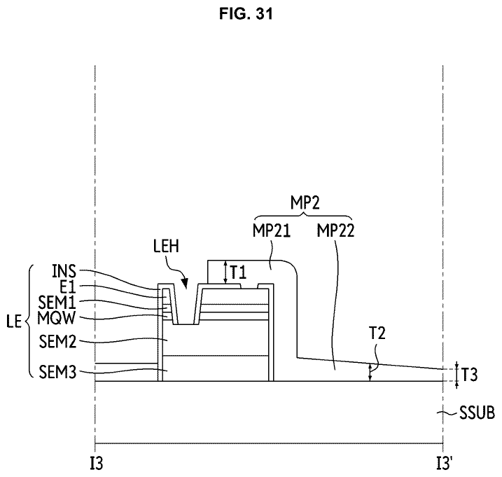

FIG. 20 is a flowchart illustrating a method of manufacturing a display device according to one or more embodiments. FIGS. 21 through 29 are example views for explaining the method of manufacturing the display device according to one or more embodiments. FIG. 30 is a layout view illustrating light emitting elements and a second mask pattern in operation S140 of FIG. 20. FIG. 31 is a cross-sectional view illustrating an example of a cross section corresponding to line the I3-I3′ of FIG. 30.

The method of manufacturing the display device according to the embodiment will now be described in detail with reference to FIGS. 20 through 31. In FIGS. 21 through 29, cross sections corresponding to the line I2-I2′ of FIG. 15 are illustrated for ease of description.

First, as illustrated in FIG. 21, a third semiconductor material layer SEML3, a second semiconductor material layer SEML2, an active material layer MQWL, a first semiconductor material layer SEML1, and a conductive material layer EL1 are formed on a semiconductor substrate SSUB (operation S110 in FIG. 20).

The semiconductor substrate SSUB may be a silicon wafer substrate and/or a sapphire substrate. A light extraction pattern layer is formed on a surface of the semiconductor substrate SSUB. The light extraction pattern layer may include convex patterns formed as hemispheres or semi-ellipsoids. The light extraction pattern layer may include convex patterns having a semicircular or semielliptical cross-sectional shape (see FIG. 7). The light extraction pattern layer may be made of a semiconductor material layer, an organic layer, and/or an inorganic layer.

Next, the third semiconductor material layer SEML3 is formed on the light extraction pattern layer. Due to the light extraction pattern layer, light extraction patterns LEP (see FIG. 17) may be formed on a surface of the third semiconductor material layer SEML3. The second semiconductor material layer SEML2 may be a semiconductor material layer doped with a second conductivity type dopant such as silicon (Si), germanium (Ge), or tin (Sn). The third semiconductor material layer SEML3 may be a semiconductor material layer whose n-type dopant is lower than a suitable threshold value (e.g., predetermined threshold value) and may be referred to as an un-doped semiconductor layer. For example, the third semiconductor material layer SEML3 may be indium aluminum gallium nitride (InAlGaN), gallium nitride (GaN), aluminum gallium nitride (AlGaN), indium gallium nitride (InGaN), aluminum nitride (AlN), and/or indium nitride (InN) whose n-type dopant is lower than a suitable threshold value (e.g., predetermined threshold value).

Next, the active material layer MQWL is formed on the second semiconductor material layer SEML2, and the first semiconductor material layer SEML1 is formed on the active material layer MQWL. The active material layer MQWL may include the same semiconductor material layer as the first semiconductor material layer SEML1 and the second semiconductor material layer SEML2. For example, when the first semiconductor material layer SEML1 and the second semiconductor material layer SEML2 include gallium nitride (GaN), the active material layer MQWL may also include gallium nitride (GaN). For example, the active material layer MQWL may include gallium nitride (GaN), indium gallium nitride (InGaN), and/or aluminum gallium nitride (AlGaN). The first semiconductor material layer SEML1 may be a semiconductor material layer doped with a first conductive type dopant such as magnesium (Mg), zinc (Zn), calcium (Ca), strontium (Sr), and/or barium (Ba).

The light extraction pattern LEP, the third semiconductor material layer SEML3, the second semiconductor material layer SEML2, the active material layer MQWL, and the first semiconductor material layer SEML1 may be formed through an epitaxial growth process on the semiconductor substrate SSUB. As the epitaxial growth process, electron beam deposition, physical vapor deposition (PVD), chemical vapor deposition (CVD), plasma laser deposition (PLD), dual-type thermal evaporation, sputtering, and/or metal-organic chemical vapor deposition (MOCVD) may be used to form the light extraction pattern LEP, the third semiconductor material layer SEML3, the second semiconductor material layer SEML2, the active material layer MQWL, and the first semiconductor material layer SEML1. The MOCVD may be preferably used, but the present disclosure is not limited thereto.

Next, the conductive material layer EL1 is formed on the first semiconductor material layer SEML1. The conductive material layer EL1 may be made of molybdenum (Mo), aluminum (Al), chromium (Cr), gold (Au), titanium (Ti), nickel (Ni), neodymium (Nd), and/or copper (Cu).

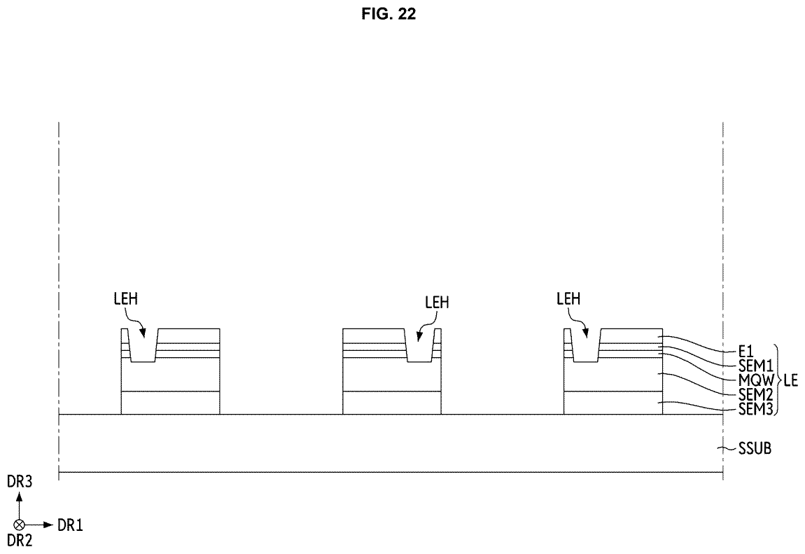

Second, as illustrated in FIG. 22, light emitting elements LE are formed by etching the third semiconductor material layer SEML3, the second semiconductor material layer SEML2, the active material layer MQWL, the first semiconductor material layer SEML1, and the conductive material layer EL1 (operation S120 in FIG. 20).

After a mask pattern is formed on the conductive material layer EL1, the third semiconductor material layer SEML3, the second semiconductor material layer SEML2, the active material layer MQWL, the first semiconductor material layer SEML1, and the conductive material layer EL1 are etched according to the mask pattern. The mask pattern may be removed after the light emitting elements LE are formed.

The third semiconductor material layer SEML3, the second semiconductor material layer SEML2, the active material layer MQWL, the first semiconductor material layer SEML1, and the conductive material layer EL1 may be etched by dry etching, wet etching, reactive ion etching (RIE), deep reactive ion etching (DRIE), inductively coupled plasma reactive ion etching (ICP-RIE), and/or the like. The dry etching may be suitable for vertical etching because anisotropic etching is possible. When the dry etching is used, an etching gas may be, but is not limited to, a chlorine (Cl₂) and/or oxygen (O₂) gas.

Next, a hole LEH is formed in each of the light emitting elements LE to pass through a conductive layer E1, a first semiconductor layer SEM1, and an active layer MQW and expose a second semiconductor layer SEM2.

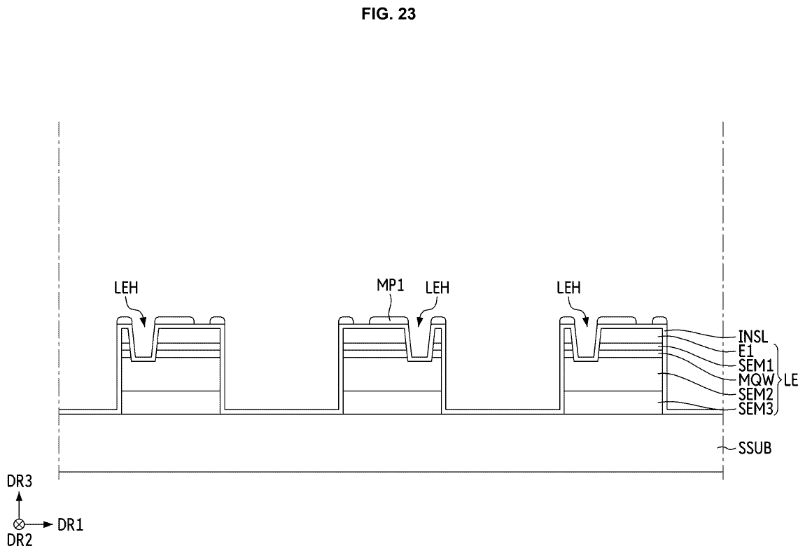

Third, as illustrated in FIG. 23, a protective material layer INSL is formed to surround the light emitting elements LE, and a first mask pattern MP1 is formed on the protective material layer INSL (operation S130 in FIG. 20).

The protective material layer INSL may be deposited on the entire surface of the semiconductor substrate SSUB. The protective material layer INSL may be formed to cover a surface and side surfaces of each of the light emitting elements LE. The protective material layer INSL may be formed on the surface of the semiconductor substrate SSUB exposed between the light emitting elements LE.

The first mask pattern MP1 may be formed to expose a portion of the hole LEH of each of the light emitting elements LE. For example, the first mask pattern MP1 may be formed not to cover the protective material layer INSL disposed on a bottom surface of the hole LEH of each of the light emitting elements LE. In addition, the first mask pattern MP1 may be placed to expose a portion of the protective material layer INSL disposed on the surface of each of the light emitting elements LE.

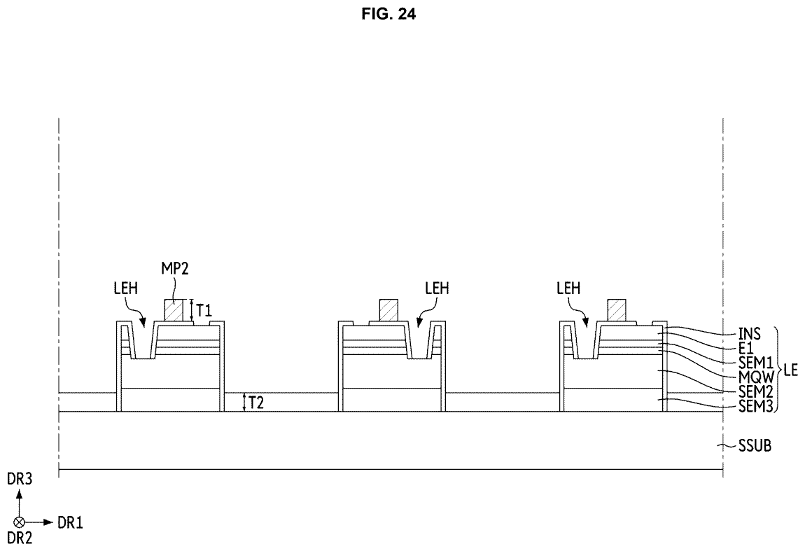

Fourth, as illustrated in FIG. 24, the protective material layer INSL not covered by the first mask pattern MP1 is etched, and a second mask pattern MP2 is formed (operation S140 in FIG. 20).

The protective material layer INSL not covered by the first mask pattern MP1 may be etched by dry etching. The protective material layer INSL disposed on the surface of each of the light emitting elements LE is etched. Accordingly, the conductive layer E1 may be exposed without being covered by the protective material layer INSL. In addition, the protective material layer INSL disposed between the light emitting elements LE may be etched, thereby exposing the semiconductor substrate SSUB.

In addition, when the protective material layer INSL is etched with a large voltage difference between a voltage of a top electrode and a voltage of a bottom electrode in a dry etching apparatus, an etching gas proceeds in the third direction DR3 and etches the protective material layer INSL. Accordingly, the protective material layer INSL disposed on sidewalls of the hole LEH of each of the light emitting elements LE may remain without being etched, even if it is not protected by the first mask pattern MP1. Therefore, the protective material layer INSL disposed on the bottom surface of the hole LEH of each of the light emitting elements LE may be etched, and the second semiconductor material layer SEML2 may be exposed in the hole LEH of each of the light emitting elements LE without being covered by the protective material layer INSL.

Next, the first mask pattern MP1 may be removed by an ashing process.

Next, the second mask pattern MP2 may be formed on a portion of the surface of each of the light emitting elements LE and between the light emitting elements LE as illustrated in FIGS. 24, 30 and 31. A thickness T1 of the second mask pattern MP2 disposed on the surface of each of the light emitting elements LE may be different from a thickness T2/T3 of the second mask pattern MP2 disposed between the light emitting elements LE.

Referring to FIGS. 30 and 31, the second mask pattern MP2 may include a first sub-mask pattern area MP21 having a first thickness T1 along the third direction DR3 and a second sub-mask pattern area MP22 having a thickness T2 and T3 smaller than the first thickness T1. Through the adjustment of a development time, the second sub-mask pattern area MP22 may be formed to have a gradually smaller thickness along the second direction DR2 as the distance from the first sub-mask pattern area MP21 increases.

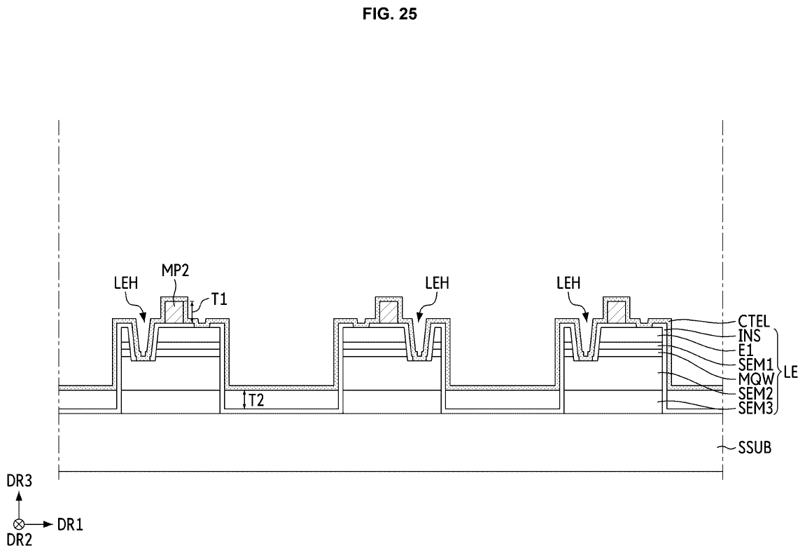

Fifth, as illustrated in FIG. 25, a contact electrode layer CTEL is deposited on the entire surface of the semiconductor substrate SSUB (operation S150 in FIG. 20).

The contact electrode layer CTEL may be formed to cover the surface and side surfaces of each of the light emitting elements LE. The contact electrode layer CTEL may be placed to cover the second mask pattern MP2. The contact electrode layer CTEL may be formed on the surface of the semiconductor substrate SSUB exposed between the light emitting elements LE.

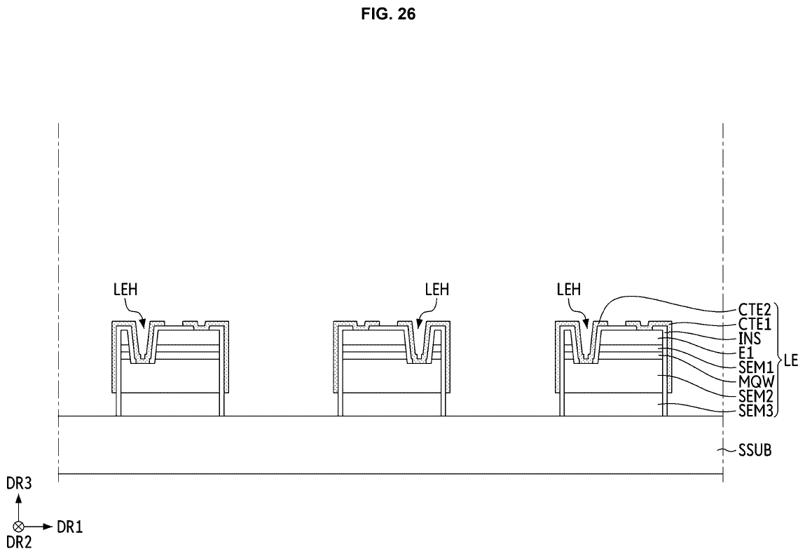

Sixth, as illustrated in FIG. 26, the second mask pattern MP2 is removed through a lift-off process, and first contact electrodes CTE1 and second contact electrodes CTE2 are formed (operation S160 in FIG. 20).

The second mask pattern MP2 may be made of negative photoresist so that it can be removed through a lift-off process. In this case, only the second mask pattern MP2 and the contact electrode layer CTEL disposed on the second mask pattern MP2 may be removed through a solvent ashing process using alcohol.

When the second mask pattern MP2 is removed, a first contact electrode CTE1 connected to the conductive layer E1 of each of the light emitting elements LE and a second contact electrode CTE2 connected to the second semiconductor layer SEM2 of each of the light emitting elements LE may be electrically isolated from each other because they are spaced (e.g., spaced apart) from each other. In addition, the first contact electrode CTE1 and the second contact electrode CTE2 may expose, instead of covering, the protective material layer INSL disposed on side surfaces of a third semiconductor layer SEM3 of each of the light emitting elements LE.

The thickness T2/T3 of the second mask pattern MP2 disposed between the light emitting elements LE may be reduced to be smaller than the thickness T1 of the second mask pattern MP2 disposed on the surface of each of the light emitting elements LE, thereby increasing the area by which the first contact electrode CTE1 and the second contact electrode CTE2 cover the protective material layer INSL disposed on side surfaces of a semiconductor stack STC of each of the light emitting elements LE. Accordingly, light travelling in the lateral direction of each light emitting element LE from among light emitted from the active layer MQW of the light emitting element LE may be reflected by the first contact electrode CTE1 and the second contact electrode CTE2 to exit from an upper surface of the light emitting element LE. Therefore, a loss of light of the light emitting element LE can be reduced, and thus the light emission efficiency of the light emitting element LE can be increased.

Next, in order to increase surface roughness of a protective layer INS by forming irregularities on a surface of the protective layer INS, the protective layer INS exposed without being covered by the first contact electrode CTE1 and the second contact electrode CTE2 on the side surfaces of the semiconductor stack STC may be exposed to an etchant at a suitable temperature (e.g., a predetermined temperature) for a suitable period of time (e.g., a predetermined period of time). The etchant may be tetramethylammonium hydroxide (TMAH), but the present disclosure is not limited thereto. The suitable temperature (e.g., the predetermined temperature) may be about 90° C., and the suitable period of time (e.g., the predetermined period of time) may be about 3 to 30 minutes. If the period of time during which the protective layer INS is exposed to the etchant is less than 3 minutes and longer than 30 minutes, irregularities may not be formed on the surface of the protective layer INS.

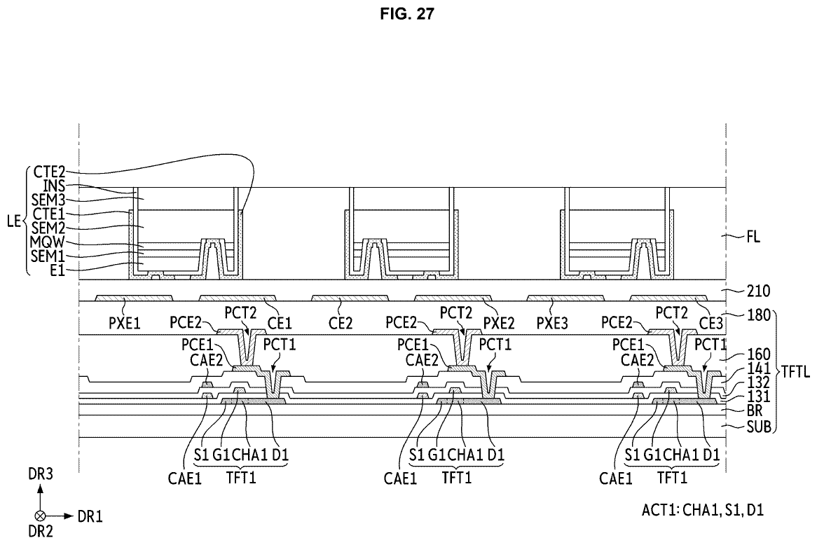

Seventh, as illustrated in FIG. 27, an insulating layer FL is formed between the light emitting elements LE, the light emitting elements LE are transferred to a first organic layer 210 disposed on pixel electrodes PXE, and the semiconductor substrate SSUB is removed (operation S170 in FIG. 20).

In order to prevent the light emitting elements LE from being separated or moved from the semiconductor substrate SSUB by external shock during the transfer process, the insulating layer FL may be formed between the light emitting elements LE. The insulating layer FL may be made of an organic layer or an inorganic layer.

Although the insulating layer FL fills the whole of the space between the light emitting elements LE in FIG. 27, the present disclosure is not limited thereto. For example, the insulating layer FL may also fill a portion of the space between the light emitting elements LE.

The light emitting elements LE may be transferred onto the first organic layer 210 disposed on the pixel electrodes PXE. At this time, the light emitting elements LE may be temporarily embedded and fixed in the first organic layer 210. Although the first contact electrode CTE1 and the second contact electrode CTE2 of each of the light emitting elements LE are disposed on the first organic layer 210 in FIG. 27, the present disclosure is not limited thereto. For example, the first organic layer 210 may be disposed on a lower surface and a portion of a side surface of the first contact electrode CTE1 and a lower surface and a portion of a side surface of the second contact electrode CTE2 of each of the light emitting elements LE. Alternatively, the first organic layer 210 may be disposed on side surfaces of the conductive layer E1 of each of the light emitting elements LE. Alternatively, the first organic layer 210 may be disposed on side surfaces of the first semiconductor layer SEM1, side surfaces of the active layer MQW, and side surfaces of the second semiconductor layer SEM2 of each of the light emitting elements LE. In this case, the first organic layer 210 may be disposed on a portion of each side surface of the second semiconductor layer SEM2.

When the fluidity of the first organic layer 210 is small or the first organic layer 210 is hard, a depth to which the light emitting elements LE are inserted or embedded in the first organic layer 210 may be very small, or the light emitting elements LE may be placed on the first organic layer 210 without being inserted or embedded in the first organic layer 210.

When the first organic layer 210 is a photosensitive organic layer such as a photoresist, the first organic layer 210 is cured (soft-baked) at a first temperature, and then at least a portion of each of the light emitting elements LE is inserted into the first organic layer 210. Then, the first organic layer 210 may be completely cured at a second temperature higher than the first temperature. The first temperature may be about 100 degrees, and the second temperature may be about 230 degrees, but the present disclosure is not limited thereto. In addition, the process of completely curing the first organic layer 210 at the second temperature may be performed for about 30 minutes.

Next, the semiconductor substrate SSUB is removed through a laser lift-off process. Alternatively, if the light emitting elements LE are transferred after being moved to a separate transfer substrate rather than the semiconductor substrate SSUB, the transfer substrate may be removed instead of the semiconductor substrate SSUB.

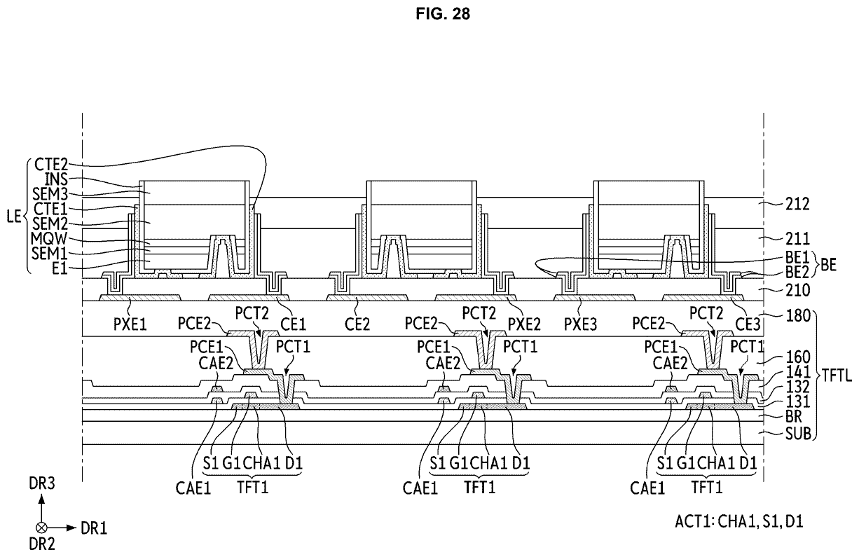

Eighth, as illustrated in FIG. 28, the insulating layer FL is removed, first connection electrodes BE1 and second connection electrodes BE2 are formed, and a second organic layer 211 and a third organic layer 212 are formed (operation S180 in FIG. 20).

The insulating layer FL may be removed using a chemical solution. The insulating layer FL may be an organic layer and/or an inorganic layer, and the chemical solution may be hydrochloric acid (HCl) and tetramethylammonium hydroxide (TMAH), but the present disclosure is not limited thereto.

If the first contact electrode CTE1 and the second contact electrode CTE2 are placed to cover the entire side surfaces of the semiconductor stack STC of each of the light emitting elements LE, the first contact electrode CTE1 and the second contact electrode CTE2 exposed on an upper surface of the semiconductor stack STC may be exposed to the chemical solution. The chemical solution may pass between the first contact electrode CTE1 and the protective layer INS and between the second contact electrode CTE2 and the protective layer INS. Accordingly, the first contact electrode CTE1 and the second contact electrode CTE2 may peel off from the protective layer INS.

However, in an embodiment of the present specification, each of the first contact electrode CTE1 and the second contact electrode CTE2 is spaced (e.g., spaced apart) from the upper surface of the semiconductor stack STC. Accordingly, the first contact electrode CTE1 and the second contact electrode CTE2 may be protected by the insulating layer FL and may not be exposed to the chemical solution. Therefore, the first contact electrode CTE1 and the second contact electrode CTE2 can be prevented from being peeled off by the chemical solution.

Next, the first connection electrodes BE1 for connecting the first contact electrodes CTE1 of the light emitting elements LE disposed on the first organic layer 210 to the pixel electrodes PXE and the second connection electrodes BE2 for connecting the second contact electrodes CTE2 to common electrodes CE are formed.

Next, the second organic layer 211 and the third organic layer 212 are formed to fix the light emitting elements LE and flatten steps caused by the light emitting elements LE.

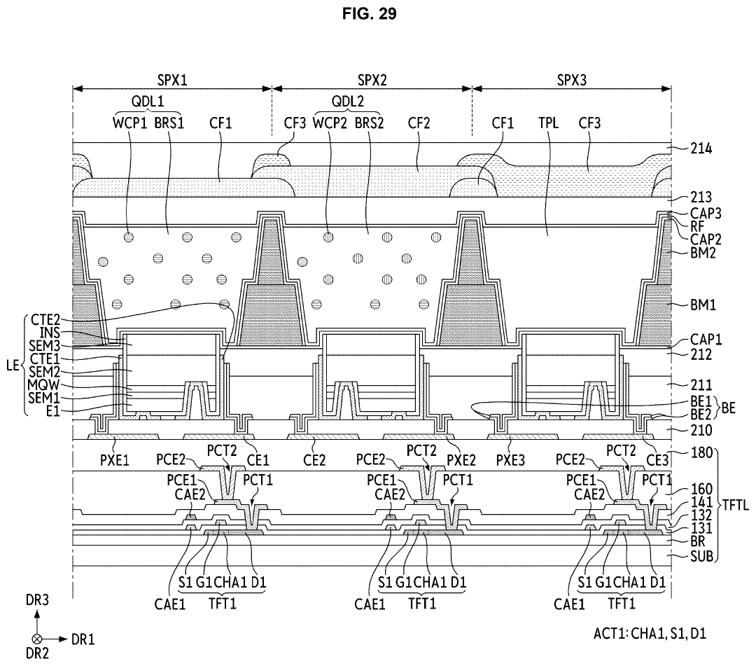

Ninth, as illustrated in FIG. 29, a light blocking layer, a wavelength conversion layer, a light transmission layer, and a color filter layer are sequentially formed (operation S190 in FIG. 20).

A first capping layer CAP1 is formed on the third organic layer 212 and the light emitting elements LE, and a first light blocking layer BM1 and a second light blocking layer BM2 are formed on the first capping layer CAP1 not to overlap the light emitting elements LE in the third direction DR3. Then, a second capping layer CAP2 is formed to cover the first light blocking layer BM1, the second light blocking layer BM2, and the first capping layer CAP1. Then, a reflective layer RF is formed to cover the second capping layer CAP2 disposed on the first light blocking layer BM1 and the second light blocking layer BM2.

Next, a first light conversion layer QDL1 is formed in each first subpixel SPX1, a second light conversion layer QDL2 is formed in each second subpixel SPX2, and a light transmission layer TPL is formed in each third subpixel SPX3. Then, a third capping layer CAP3 is formed to cover the first light conversion layers QDL1, the second light conversion layers QDL2, and the light transmission layers TPL. Then, a fourth organic layer 213 is formed on the third capping layer CAP3.

Next, a first color filter CF1 is formed on the fourth organic layer 213 to overlap each of the first light conversion layers QDL1 in the third direction DR3, a second color filter CF2 is formed to overlap each of the second light conversion layers QDL2 in the third direction DR3, and a third color filter CF3 is formed to overlap each of the light transmission layers TPL in the third direction DR3. In each area overlapping the first light blocking layer BM1 and the second light blocking layer BM2 in the third direction DR3, the first color filter CF1, the second color filter CF2, and the third color filter CF3 may all be formed.

Next, a fifth organic layer 214 is formed on the first color filters CF1, the second color filters CF2, and the third color filters CF3.

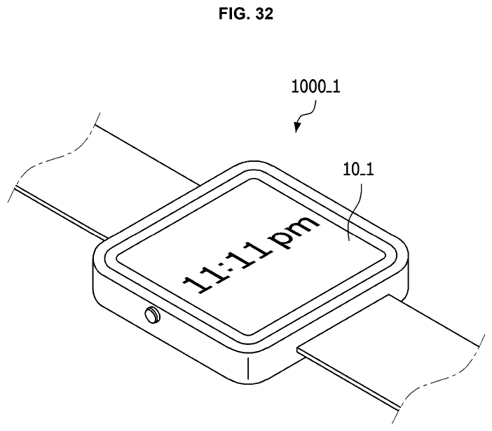

FIG. 32 is an example view of a smart watch including a display device according to one or more embodiments.

Referring to FIG. 32, a display device 10_1 according to one or more embodiments may be applied to a smart watch 1000_1 which is one of smart devices.

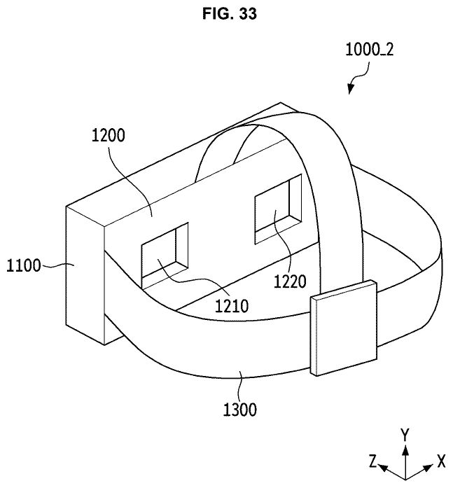

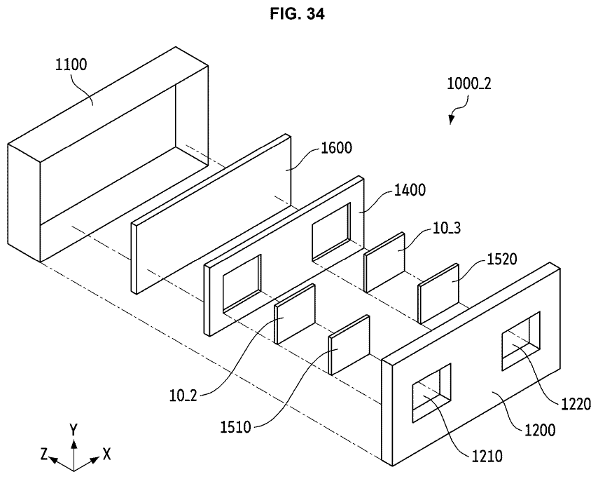

FIGS. 33 and 34 are example views of a virtual reality (VR) device including a display device according to one or more embodiments.

Referring to FIGS. 33 and 34, a head mounted display device 1000_2 according to one or more embodiments includes a first display device 10_2, a second display device 10_3, a display device housing 1100, a housing cover 1200, a first eyepiece 1210, a second eyepiece 1220, a head mounted band 1300, a middle frame 1400, a first optical member 1510, a second optical member 1520, and a control circuit board 1600.

The first display device 10_2 provides an image to a user's left eye, and the second display device 10_3 provides an image to the user's right eye. Each of the first display device 10_2 and the second display device 10_3 is substantially the same as the display device 10 described with reference to FIGS. 1 and 2. Therefore, a description of the first display device 10_2 and the second display device 10_3 will be omitted.

The first optical member 1510 may be disposed between the first display device 10_2 and the first eyepiece 1210. The second optical member 1520 may be disposed between the second display device 10_3 and the second eyepiece 1220. Each of the first optical member 1510 and the second optical member 1520 may include at least one convex lens.

The middle frame 1400 may be disposed between the first display device 10_2 and the control circuit board 1600 and may be disposed between the second display device 10_3 and the control circuit board 1600. The middle frame 1400 supports and fixes the first display device 10_2, the second display device 10_3, and the control circuit board 1600.

The control circuit board 1600 may be disposed between the middle frame 1400 and the display device housing 1100. The control circuit board 1600 may be connected to the first display device 10_2 and the second display device 10_3 through a connector. The control circuit board 1600 may convert an image source received from the outside into digital video data DATA and transmit the digital video data DATA to the first display device 10_2 and the second display device 10_3 through the connector.

The control circuit board 1600 may transmit the digital video data DATA corresponding to a left image optimized for a user's left eye to the first display device 10_2 and transmit the digital video data DATA corresponding to a right image optimized for the user's right eye to the second display device 10_3. Alternatively, the control circuit board 1600 may transmit the same digital video data DATA to the first display device 10_2 and the second display device 10_3.

The display device housing 1100 houses the first display device 10_2, the second display device 10_3, the middle frame 1400, the first optical member 1510, the second optical member 1520, and the control circuit board 1600. The housing cover 1200 is placed to cover an open surface of the display device housing 1100. The housing cover 1200 may include the first eyepiece 1210 on which a user's left eye is placed and the second eyepiece 1220 on which the user's right eye is placed. Although the first eyepiece 1210 and the second eyepiece 1220 are disposed separately in FIGS. 33 and 34, the present disclosure is not limited thereto. The first eyepiece 1210 and the second eyepiece 1220 may also be combined into one.

The first eyepiece 1210 may be aligned with the first display device 10_2 and the first optical member 1510, and the second eyepiece 1220 may be aligned with the second display device 10_3 and the second optical member 1520. Therefore, a user can view an image of the first display device 10_2, which is enlarged as a virtual image by the first optical member 1510, through the first eyepiece 1210 and can view an image of the second display device 10_3, which is enlarged as a virtual image by the second optical member 1520, through the second eyepiece 1220.

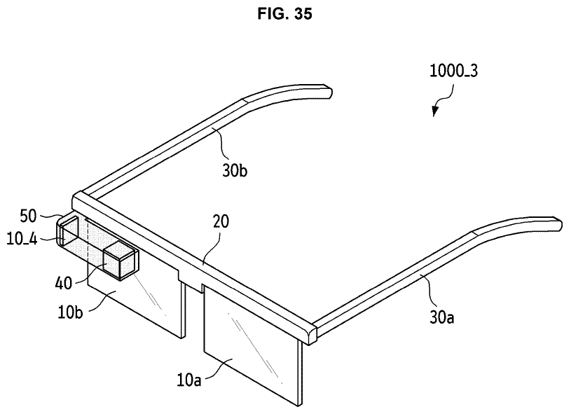

The head mounted band 1300 fixes the display device housing 1100 to a user's head so that the first eyepiece 1210 and the second eyepiece 1220 of the housing cover 1200 are kept placed on the user's left and right eyes, respectively. When the display device housing 1200 is implemented to be lightweight and small, the head mounted display device 1000_2 may include an eyeglass frame as illustrated in FIG. 35 instead of the head mounted band 1300.

In addition, the head mounted display device 1000_2 may further include a battery for supplying power, an external memory slot for accommodating an external memory, and an external connection port and a wireless communication module for receiving an image source. The external connection port may be a universe serial bus (USB) terminal, a display port, or a high-definition multimedia interface (HDMI) terminal, and the wireless communication module may be a 5G communication module, a 4G communication module, a Wi-Fi module, or a Bluetooth module.

FIG. 35 is an example view of a VR device including a display device according to one or more embodiments. FIG. 35 illustrates a VR device 1000_3 to which a display device 10_4 according to one or more embodiments has been applied.

Referring to FIG. 35, the VR device 1000_3 according to one or more embodiments may be a device in the form of glasses. The VR device 1000_3 according to the embodiment may include the display device 10_4, a left lens 10a, a right lens 10b, a support frame 20, eyeglass frame legs 30a and 30b, a reflective member 40, and a display device housing 50.

In FIG. 35, a case where the VR device 1000_3 is a glasses-type display device including the eyeglass frame legs 30a and 30b is illustrated as an example. That is, the VR device 1000_3 according to the embodiment is not limited to the one illustrated in FIG. 35 and can be applied in various forms to various other electronic devices.

The display device housing 50 may include the display device 10_4 and the reflective member 40. An image displayed on the display device 10_4 may be reflected by the reflective member 40 and provided to a user's right eye through the right lens 10b. Accordingly, the user may view a VR image displayed on the display device 10_4 through the right eye.

Although the display device housing 50 is disposed at a right end of the support frame 20 in FIG. 35, the present disclosure is not limited thereto. For example, the display device housing 50 may also be disposed at a left end of the support frame 20. In this case, an image displayed on the display device 10_4 may be reflected by the reflective member 40 and provided to the user's left eye through the left lens 10a. Accordingly, the user may view a VR image displayed on the display device 10_4 through the left eye. Alternatively, the display device housing 50 may be disposed at both the right end and the left end of the support frame 20. In this case, the user may view a VR image displayed on the display device 10_4 through both the left eye and the right eye.

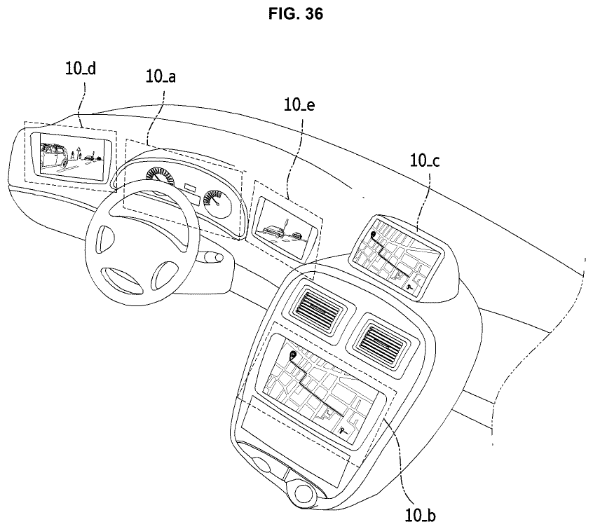

FIG. 36 is an example view illustrating a vehicle instrument cluster and center fascia including display devices according to one or more embodiments. FIG. 36 illustrates a vehicle to which display devices 10_a through 10_e according to one or more embodiments have been applied.

Referring to FIG. 36, the display devices 10_a through 10_c according to the embodiment may be applied to an instrument cluster of the vehicle, a center fascia of the vehicle, or a center information display (CID) disposed on a dashboard of the vehicle. In addition, the display devices 10_d and 10_e according to the embodiment may be applied to room mirror displays that replace side mirrors of the vehicle.

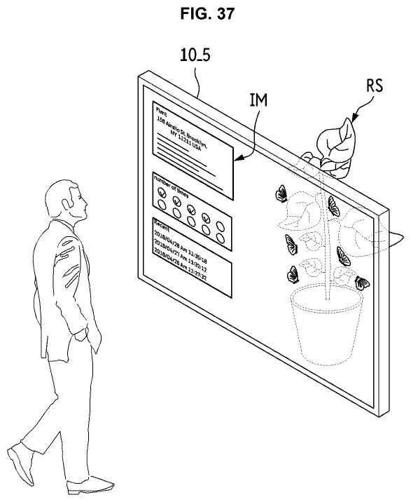

FIG. 37 is an example view of a transparent display device including a display device according to one or more embodiments.

Referring to FIG. 37, a display device 10_5 according to one or more embodiments may be applied to a transparent display device. The transparent display device may transmit light while displaying an image IM. Therefore, a user located in front of the transparent display device cannot only view the image IM displayed on the display device 10_5 but also view an object RS or the background located behind the transparent display device. When the display device 10_5 is applied to the transparent display device, a substrate of the display device 10_5 may include a light transmitting portion that can transmit light or may be made of a material that can transmit light.

It should be understood, however, that the aspects and features of embodiments of the present disclosure are not restricted to the one set forth herein. The above and other aspects of the present disclosure will become more apparent to one of ordinary skill in the art to which the present disclosure pertains by referencing the claims, with equivalents thereof to be included therein.

What is claimed is:

1. A display device comprising:
a substrate;
a pixel electrode on the substrate;
an organic layer on the pixel electrode; and
a light emitting element on the organic layer,
wherein the light emitting element comprises:
a semiconductor stack;
a protective layer on a side surface of the semiconductor stack; and
a contact electrode on the protective layer,
wherein a portion of the side surface of the semiconductor stack is exposed without being covered by the contact electrode, and the contact electrode is spaced from an upper surface of the semiconductor stack.

2. The display device of claim 1, wherein the semiconductor stack further comprises:
a first semiconductor layer on the organic layer and comprising a first semiconductor material layer doped with a first conductivity type dopant;
an active layer on the first semiconductor layer; and
a second semiconductor layer on the active layer and comprising a second semiconductor material layer doped with a second conductivity type dopant,
wherein the contact electrode is on an entire side surface of the first semiconductor layer, an entire side surface of the active layer, and a portion of a side surface of the second semiconductor layer.

3. The display device of claim 1, wherein the light emitting element further comprises:
a conductive layer between the organic layer and the semiconductor stack,
the contact electrode on the protective layer being connected to the conductive layer which is exposed without being covered by the protective layer.

4. The display device of claim 3, wherein a distance between the upper surface of the semiconductor stack and the contact electrode in a height direction of the light emitting element is greater than 100 nm.

5. The display device of claim 3, wherein the light emitting element further comprises light extraction patterns on the upper surface of the semiconductor stack and has a concave cross-sectional shape.

6. The display device of claim 5, wherein a distance between the upper surface of the semiconductor stack and the contact electrode in a height direction of the light emitting element is greater than a maximum length of one of the light extraction patterns in the height direction of the light emitting element.

7. The display device of claim 3, wherein the protective layer comprises a first side area exposed on a side surface of the light emitting element without being covered by the contact electrode and a second side area covered by the contact electrode, and surface roughness of the first side area is greater than surface roughness of the second side area.

8. The display device of claim 3, further comprising a connection electrode connected to the pixel electrode through a connection hole penetrating the organic layer and connected to the contact electrode on the side surface of the light emitting element.

9. The display device of claim 8, wherein a distance between the upper surface of the semiconductor stack and the connection electrode in a height direction of the light emitting element is greater than 100 nm.

10. A display device comprising:
a substrate;
a pixel electrode on the substrate;
an organic layer on the pixel electrode and a common electrode; and
a light emitting element on the organic layer,
wherein the light emitting element comprises:
a semiconductor stack;
a conductive layer between the organic layer and the semiconductor stack;
a protective layer on side surfaces of the conductive layer and side surfaces of the semiconductor stack;
a first contact electrode on the protective layer and connected to the conductive layer exposed without being covered by the protective layer; and
a second contact electrode on the protective layer and in a hole penetrating the conductive layer and a portion of the semiconductor stack,
wherein each of the first contact electrode and the second contact electrode is spaced from an upper surface of the semiconductor stack.

11. The display device of claim 10, wherein a portion of a first side surface from among the side surfaces of the semiconductor stack is exposed without being covered by the first contact electrode, and a portion of a second side surface from among the side surfaces of the semiconductor stack is exposed without being covered by the second contact electrode.

12. The display device of claim 10, wherein the semiconductor stack further comprises:
a first semiconductor layer on the organic layer and comprising a first semiconductor material layer doped with a first conductivity type dopant;
an active layer on the first semiconductor layer; and
a second semiconductor layer on the active layer and comprising a second semiconductor material layer doped with a second conductivity type dopant,
wherein the first contact electrode is on a first side surface of the first semiconductor layer, a first side surface of the active layer, and a portion of a first side surface of the second semiconductor layer, and the second contact electrode is on a second side surface of the first semiconductor layer, a second side surface of the active layer, and a portion of a second side surface of the second semiconductor layer.

13. The display device of claim 10, wherein a distance between the upper surface of the semiconductor stack and the first contact electrode or the second contact electrode in a height direction of the light emitting element is greater than 100 nm.

14. The display device of claim 10, wherein the light emitting element further comprises a light extraction pattern on the upper surface of the semiconductor stack and has a concave cross-sectional shape.

15. The display device of claim 14, wherein a distance between the upper surface of the semiconductor stack and the first contact electrode or the second contact electrode in a height direction of the light emitting element is greater than a maximum length of the light extraction pattern in the height direction of the light emitting element.

16. The display device of claim 10, wherein the protective layer comprises a first side area exposed on a side surface of the light emitting element without being covered by the first contact electrode or the second contact electrode and a second side area covered by the first contact electrode or the second contact electrode, and surface roughness of the first side area is greater than surface roughness of the second side area.

17. The display device of claim 10, further comprising:
a first connection electrode connected to the pixel electrode through a first connection hole penetrating the organic layer and connected to the first contact electrode on a side surface of the light emitting element; and
a second connection electrode connected to the common electrode through a second connection hole penetrating the organic layer and connected to the second contact electrode on another side surface of the light emitting element.

18. The display device of claim 17, wherein a distance between the upper surface of the semiconductor stack and the first connection electrode or the second connection electrode in a height direction of the light emitting element is greater than 100 nm.

19. A method of manufacturing a display device, the method comprising:
forming a second semiconductor material layer, an active material layer, a first semiconductor material layer, and a conductive material layer on a semiconductor substrate;
forming light emitting elements, each of the light emitting elements comprising a second semiconductor layer, an active layer, a first semiconductor layer and a conductive layer, by etching the second semiconductor material layer, the active material layer, the first semiconductor material layer, and the conductive material layer;
forming a hole, which penetrates the conductive layer, the first semiconductor layer, and the active layer, in each of the light emitting elements;
forming a protective material layer which surrounds each of the light emitting elements and forming a protective layer by patterning the protective material layer;
forming a mask pattern on the protective layer and forming a contact electrode layer;
forming a first contact electrode connected to the conductive layer in each of the light emitting elements and a second contact electrode connected to the second semiconductor layer in the hole by removing the mask pattern;
transferring the light emitting elements onto an organic layer on pixel electrodes and common electrodes such that the conductive layer in each of the light emitting elements faces a corresponding pixel electrode of the pixel electrodes and a corresponding common electrode of the common electrodes; and
forming a first connection electrode which connects the first contact electrode of each of the light emitting elements to one of the pixel electrodes and a second connection electrode which connects the second contact electrode to one of the common electrodes.

20. The method of claim 19, wherein the mask pattern comprises:
a first sub-mask pattern area extending in a first direction and has a first thickness; and
a second sub-mask pattern area having a thickness smaller than the first thickness and have a gradually smaller thickness along a second direction intersecting the first direction as a distance from the first sub-mask pattern area increases.
